(19) United States
(12) Patent Application Publication
(10) Pub. No.: US 2009/0086523 A1
(43) Pub. Date: Apr. 2, 2009

(54) Integrated circuit and method of forming an integrated circuit

(76) Inventors: Jessica Hartwich, Dresden (DE); Lars Dreeskornfeld, Dresden (DE)

Correspondence Address: FAY KAPLUN & MARCIN, LLP, 150 BROADWAY, SUITE 702, NEW YORK, NY, 10038, US

(21) Appl. No.: 11/904,783

(22) Filed: Sep. 28, 2007

(51) Int. Cl. G11C 5/06; H01L 21/336

(52) U.S. Cl. 365/72; 438/283; 257/E21.409

(57) ABSTRACT

An integrated circuit comprises a memory cell array portion and a support circuitry portion. The memory cell array portion comprises at least one bitline and at least one wordline, which is disposed above the bitline. The support circuitry portion comprises a FinFET comprising a gate electrode. An upper side of a portion of the gate electrode is disposed at the same height as an upper side of a portion of the bitline. A method of manufacturing an integrated circuit comprises the steps of forming a memory cell array and forming a support circuitry. The step of forming the memory cell array comprises forming a bitline and forming a wordline disposed above the bitline. The step of forming the support circuitry comprises forming a FinFET. The step of forming the FinFET comprises forming a gate electrode, an upper side of a portion of the gate electrode being formed at the same height as an upper side of a portion of the bitline.

### BACKGROUND OF THE INVENTION

1. Field of the Invention

The present invention relates to an integrated circuit as well as to a method of manufacturing such an integrated circuit. Moreover, the specification refers to a memory device as well as to a method of manufacturing such a memory device.

2. Description of the Related Art

Generally, in the field of semiconductor technology, circuit portions of different functionality are combined into a single integrated circuit. With continually higher demands being made on the capabilities of integrated circuits, different circuit portions on the same integrated circuit chip are desired to be improved in different ways, depending on the functional role and technical demands placed on each circuit portion. Accordingly, different kinds of optimizations are attempted for different circuit portions on the same chip. Moreover, it is desirable to avoid a complication of the manufacturing process at the same time.

For example, in an integrated circuit comprising a memory cell array portion and a support circuitry portion it is often desired to optimize the layout of the memory cell array portion while simultaneously improving the performance of the associated support circuitry in the support circuitry portion.

### BRIEF SUMMARY OF THE INVENTION

Various aspects of the invention are listed in independent claims 1, 8, 10, 13, and 19, respectively.

Further aspects are listed in the respective dependent claims.

### DESCRIPTION OF THE DRAWINGS

In the Figures:

FIG. 1A shows a top view of a first portion of a semiconductor substrate, after performing initial processing steps for manufacturing an integrated circuit according to a first embodiment;

FIGS. 1B and 1C show mutually perpendicular cross-sectional views of the first portion of the semiconductor substrate as shown in FIG. 1A;

FIG. 2A shows a top view of a second portion of the semiconductor substrate, after performing the initial processing steps according to the first embodiment;

FIGS. 2B and 2C show mutually perpendicular cross-sectional views of the second portion of the semiconductor substrate as shown in FIG. 2A;

FIGS. 3A to 3C show a top view and corresponding mutually perpendicular cross-sectional views of the second portion of the semiconductor substrate, after performing further processing steps;

FIGS. 4 and 5 respectively show top views of the first portion of the semiconductor substrate and corresponding mutually perpendicular cross-sectional views, after performing respective further processing steps;

FIGS. 6 and 7 respectively show top views of the second portion of the semiconductor substrate and corresponding mutually perpendicular cross-sectional views, after performing respective further processing steps;

FIGS. 8 to 13 respectively show top views of the second portion of the semiconductor substrate along with several corresponding cross-sectional views, after performing respective further processing steps;

FIGS. 14A to 14C show a top view and corresponding mutually perpendicular cross-sectional views of the first portion of the semiconductor substrate, after performing further processing steps;

FIGS. 15A to 15F show a top view and corresponding cross-sectional views of the second portion of the semiconductor substrate, after performing further processing steps;

FIGS. 16A to 16C show a top view and corresponding mutually perpendicular cross-sectional views of the first portion of the semiconductor substrate after performing further processing steps;

FIGS. 17A and 17B show mutually perpendicular cross-sectional views of the first portion of the semiconductor substrate, after performing further processing steps;

FIG. 18 shows a cross-sectional view of the second portion of the semiconductor substrate, after performing the processing steps;

FIGS. 19 to 21 respectively show top views and corresponding mutually perpendicular cross-sectional views of the first portion of the semiconductor substrate, after performing respective further processing steps;

FIGS. 22A to 22C respectively show a top view and corresponding mutually perpendicular cross-sectional views of a first portion of a semiconductor substrate after performing initial processing steps for manufacturing an integrated circuit according to a second embodiment;

FIGS. 23 to 25 respectively show top views and corresponding mutually perpendicular cross-sectional views of the first portion of the semiconductor substrate of FIG. 22, after performing respective further processing steps;

FIGS. 26A to 26C respectively show a top view and corresponding mutually perpendicular cross-sectional views of a second portion of the semiconductor substrate of FIG. 22, after performing further processing steps;

FIGS. 27A to 27C respectively show a top view of the first portion of the semiconductor substrate and corresponding mutually perpendicular cross-sectional views, after performing further processing steps;

FIGS. 28A to 28F respectively show a top view and corresponding cross-sectional views of the second portion of the semiconductor substrate, covered by a patterned mask after further processing steps;

FIGS. 29A to 29C respectively show a top view and corresponding mutually perpendicular cross-sectional views of the first portion of the semiconductor substrate, covered by a patterned mask after further processing steps;

FIGS. 30A to 30F show a top view and corresponding cross-sectional views of the second portion of the semiconductor substrate after etching and removal of the mask; and

FIGS. 31A to 31C show a top view and corresponding mutually perpendicular cross-sectional views of the first section of the semiconductor substrate after etching and removal of the mask.

In the Figures, like numerals refer to the same or similar functionality throughout the several views.

### DESCRIPTION OF THE PREFERRED EMBODIMENTS

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “left”, “right”, etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

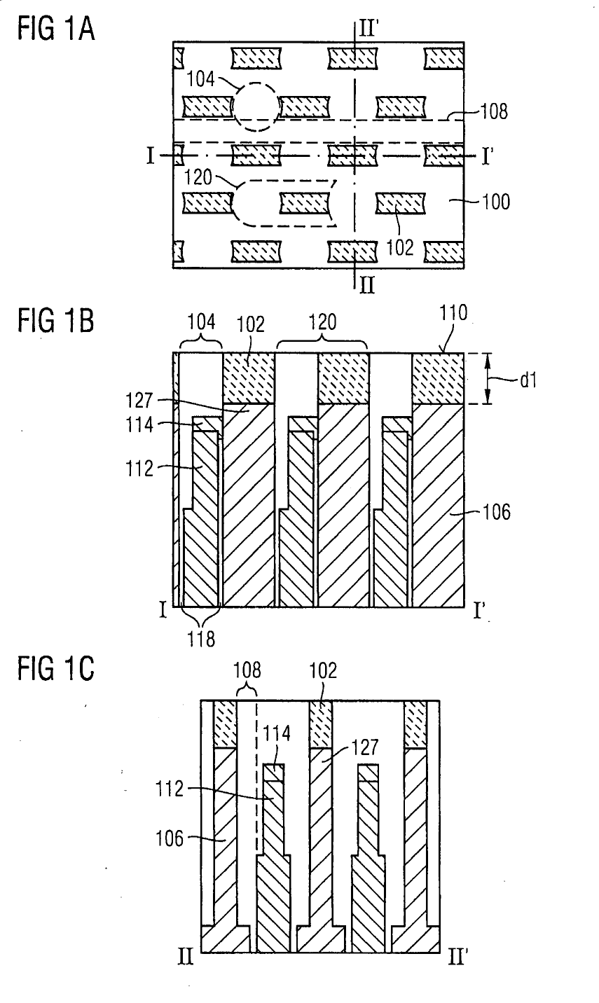

By making reference to FIGS. 1 to 21, an exemplary manufacturing process for manufacturing an integrated circuit based on a semiconductor substrate will be explained according to a first embodiment. The terms “wafer”, “substrate” or “semiconductor substrate” used in the following description may include any semiconductor-based structure or any structure having a semiconductor surface. Wafer and structure are to be understood to include silicon, silicon on insulator (SOI), silicon on sapphire (SOS), doped an undoped semiconductors, epitaxial layers of silicon supported by a base semiconductor foundation, and other semiconductor structures. Although in the present embodiment the semiconductor is silicon based, in alternative embodiments the semiconductor could be silicon-germanium, germanium, or gallium arsenide or other group III-V or group II-VI semiconductor materials, among others.

FIG. 1A shows a top view of a first portion of the semiconductor substrate in which a memory cell array of the integrated circuit is to be formed. FIG. 1A depicts the memory cell array portion in a state after having undergone initial processing steps that have lead to a pattern of islands of silicon nitride 102 surrounded by silicon dioxide 100 to be visible at the surface of the memory cell array portion, with no part of the substrate itself visible from above. The pattern shown may have been formed e.g. by processing steps conventionally employed when manufacturing a DRAM memory device.

FIGS. 1B and 1C show cross-sectional views of the memory cell array portion in the state depicted in FIG. 1A. The cross-sectional view shown in FIG. 1B is taken between I and I′ whereas the cross-sectional view shown in FIG. 1C is taken between II and II′, as can be seen from the corresponding dash-dotted lines in FIG. 1A. The silicon nitride islands 102 can be seen to extend for a thickness d1 below the wafer surface 110 and to be sited on top of portions of the semiconductor substrate 106.

In the I-I′ direction, the silicon nitride islands 102 and underlying substrate portions 106 are separated by deep trenches 104 that have been formed in the substrate 106 to provide storage capacitors, one for each memory cell 120 of the memory cell array. Each storage capacitor comprises an inner electrode 112 of e.g. polysilicon and a thin dielectric layer 118 that insulates the inner electrode from the surrounding substrate 106. A buried strap 114 made of polysilicon connects the inner electrode 112 to a portion of the substrate 106 in the vicinity of the silicon nitride islands 102 where a source/drain region of an access transistor of the memory cell is to be formed in later processing steps.

In the II-II′ direction, the silicon nitride islands and underlying substrate 106 portions are separated by shallow isolation trenches 108 as delineated in FIGS. 1A and 1C. For manufacturing the integrated circuit up to the state shown in FIGS. 1A to 1C, the substrate 106 is first covered by a contiguous layer of silicon nitride of thickness d1. Afterwards, the deep trenches 104 are formed through the silicon nitride layer into the substrate 106. In a further step, the shallow isolation trenches 108 are formed through the silicon nitride layer into the substrate 106, thus leading to a patterning of the wafer surface as shown in FIG. 1A, wherein the silicon nitride islands 102 remain of the silicon nitride layer, separated from each other by the deep trenches 104 and the shallow isolation trenches 108. The outline of the silicon nitride islands 102 when seen from above as in FIG. 1A delineates active areas 127 of the underlying substrate 106 that are electrically insulated from each other. In the present embodiment, memory cells 120 are arranged in a checkerboard pattern. However, alternative embodiments may comprise any other suitable patterns.

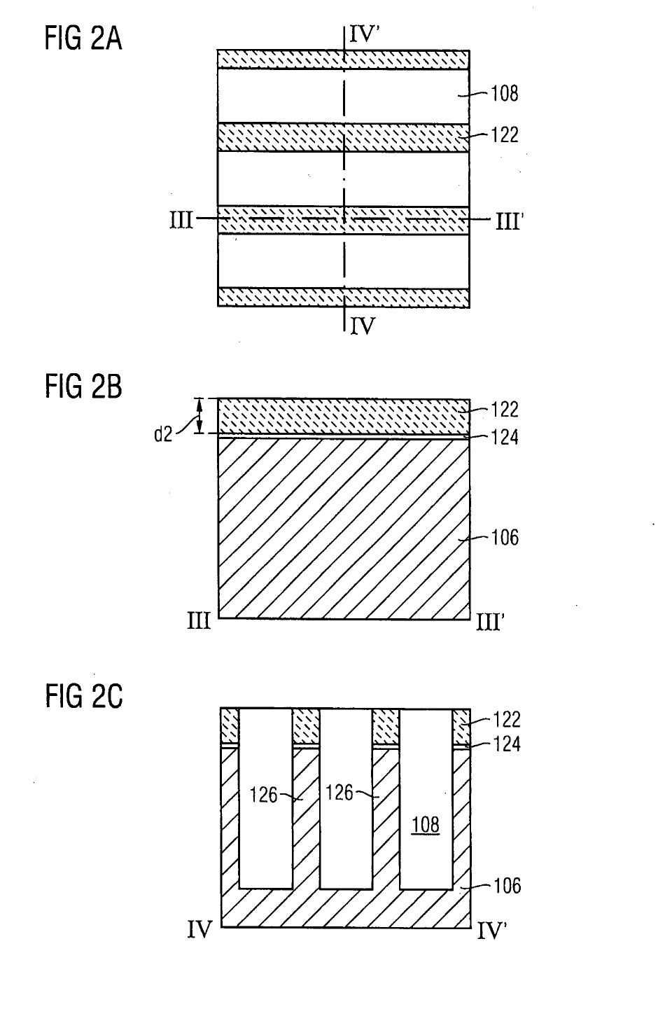

FIG. 2A shows a top view of a second portion of the wafer from which the integrated circuit is to be formed, in a state where initial processing steps have been performed. The wafer surface shown in FIG. 2A exhibits a striped pattern of alternating surface regions of silicon dioxide 108 and silicon nitride 122. FIG. 2B shows a cross-sectional view taken between III and III′ as marked in FIG. 2A. The silicon nitride strips 122 can be seen to be of thickness d2 and to be separated from the substrate 106 by a thin pad oxide layer 124, which is absent in alternative embodiments. FIG. 2C shows a cross-sectional view of the same structure depicted in FIGS. 2A and 2B, taken between IV and IV′ as can be seen in FIG. 2A. The shallow isolation trenches 108 are shown to extend through the silicon nitride layer 122 and the pad oxide layer 124 into the substrate 106, thus electrically insulating from each other active areas 126 of the substrate 106, which are located below the silicon nitride strips 122.

In order to arrive at the structure shown in FIGS. 2A to 2C, shallow isolation trenches 108 may be etched into the semiconductor substrate 106 by using standard lithographic techniques, after having covered the substrate 106 by the pad oxide 124 and silicon nitride 122 layers. The shallow isolation trenches 108 may then be filled with silicon dioxide or other electrically insulating oxide materials using e.g. by using conventional spin-on dielectric and high-density plasma deposition processes, each of which may be followed by a chemical-mechanical planarization step. Optionally, the resulting planarized surface pattern shown in FIG. 2A may be subjected to an anti-punch implant. The steps of forming the shallow isolation trenches 108 including etching, filling, and planarization may be carried out simultaneously in the first portion of the semiconductor substrate 106, shown in FIGS. 1A to 1C, and in the second portion of the semiconductor substrate 106, shown in FIGS. 2A to 2C.

Accordingly, embodiments of the invention enable processing steps for forming a memory cell array portion of an integrated circuit to be carried out simultaneously with processing steps for forming a support circuitry portion of the integrated circuit, the memory cell array portion corresponding to the semiconductor substrate portion shown in FIG. 1A to 1C and the support circuitry portion corresponding to the semiconductor substrate portion shown in FIGS. 2A to 2C. Thus, the active areas 127 in the memory cell array portion are formed simultaneously with the active areas 126 in the support circuitry portion.

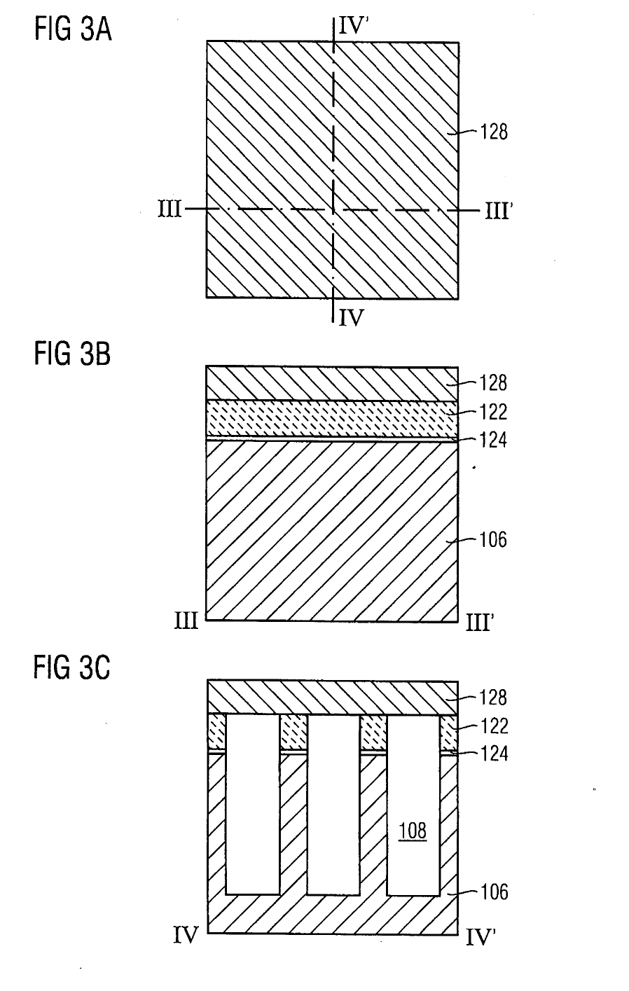

In order to carry out further processing steps for forming a wordline-over-bitline type structure in the memory cell array portion while leaving unaffected the support circuitry portion, the support circuitry portion in its entirety is covered by a layer of polysilicon, as viewed from above in FIG. 3A. FIG. 3B shows a corresponding cross-sectional view of the support circuitry portion along the dash-dotted line from III to III′ in FIG. 3A. FIG. 3C likewise shows a cross-sectional view taken between IV and IV′ as indicated in FIG. 3A. The layer 128 of polysilicon may e.g. initially be formed on the entire wafer surface. After masking the support circuitry portion by a lithographic mask, the polysilicon layer may be removed by from the memory cell array portion by etching and subsequent stripping of the lithographic mask. The polysilicon layer 128 thus formed covers the support circuitry portion only, while leaving the memory cell array portion essentially as shown in FIGS. 1A to 1C.

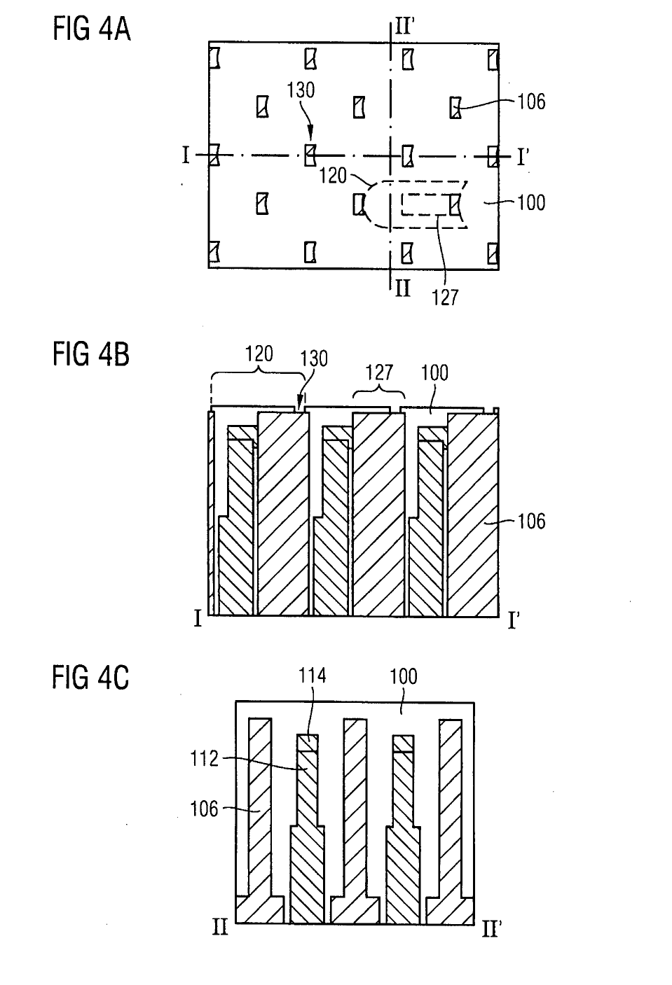

In the following, several processing steps for forming the desired wordline-over-bitline structure in the memory cell array portion are carried out. First, silicon oxide 100 as shown in FIG. 1A is reset in a deglazing step, e.g. to an extent of approximately two thirds of the thickness d1 of the silicon nitride layer 102, as shown in FIG. 1B. In the top view of FIG. 4A and corresponding cross-sectional views of FIGS. 4B and 4C, the wafer surface can be seen to be predominantly covered by a silicon dioxide layer 100 in the memory cell array portion, with openings 130 for connecting the memory cells 120 to bitlines having been formed through which the underlying substrate 106 is exposed. An active area 127 of a memory cell 120 has been marked by a dashed line to demonstrate the position of the openings 130 at the rightmost ends of the respective active areas 127 of the memory cells 120. The thin silicon dioxide layer 100 covers also the support circuitry portion, on top of the polysilicon layer 128 shown in FIGS. 3A to 3C.

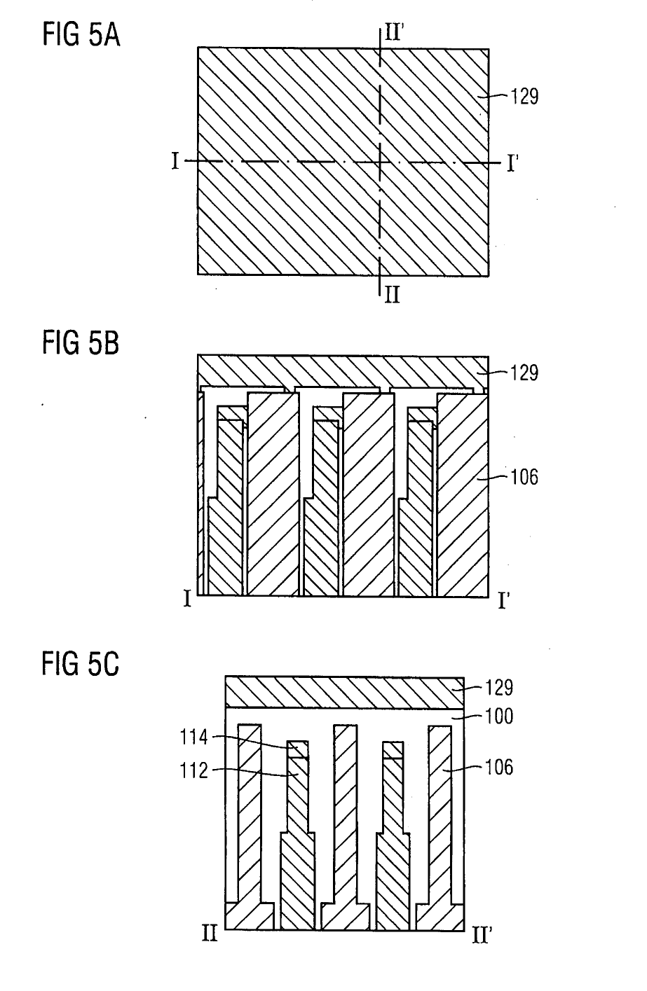

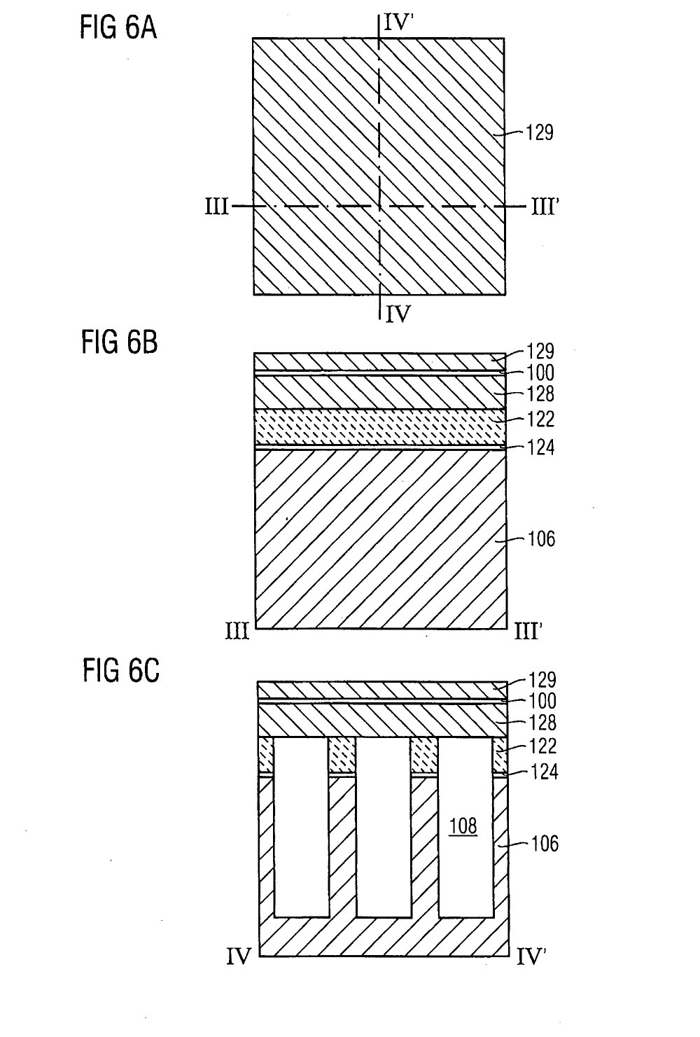

In a subsequent step, a second polysilicon layer 129 is deposited over the entire wafer surface, covering both the memory cell array and support circuitry portions. FIGS. 5A to 5C depict the state of the memory cell array portion after the step of depositing the second polysilicon layer 129. Likewise, FIGS. 6A to 6C depict the state of the support circuitry portion after the same step of depositing the second polysilicon layer 129. The cross-sectional views of FIGS. 6B and 6C show the second polysilicon layer 129 to be deposited over the first polysilicon layer 128 and silicon dioxide layer 100.

At this stage, a resist mask is placed over the memory cell array portion. Both polysilicon layers 128, 129 and the thin silicon dioxide layer 100 separating them are etched away in the support circuitry portion e.g. by reactive ion etching (RIE). In this way, the support circuitry portion is returned to the state shown in FIGS. 2A to 2C. The resist mask is then stripped from the memory cell array portion, likewise returning it to the state shown in FIGS. 5A to 5C.

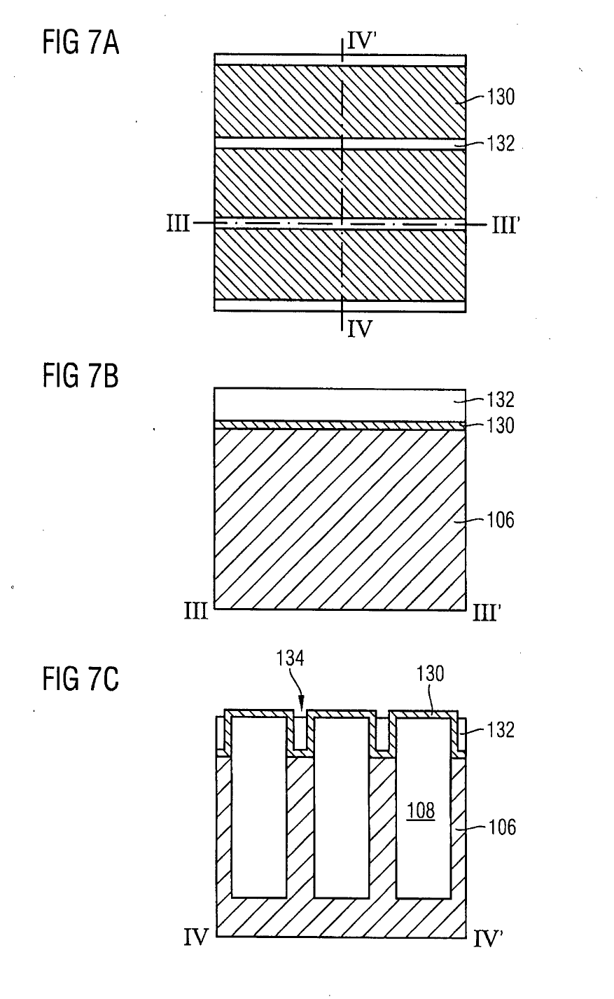

In following processing steps, the support circuitry portion is processed to form the structure shown in FIGS. 7A to 7C while the memory cell array portion remains constantly covered by the polysilicon layer 129 shown in FIGS. 5A to 5C. First, after a deglazing step, the silicon nitride strips 122 visible in FIG. 6C are removed by selective etching. A liner of polysilicon 130 is then deposited upon the entire wafer surface, which in the memory cell array portion merely adds to the thickness of the polysilicon layer 129. Then, grooves 134 that were formed by removing the silicon nitride strips 122 visible in FIG. 6C are filled with oxide material 132 such as silicon dioxide. The oxide material is subsequently recessed to remove any oxide coverage on the polysilicon liner 130 outside the grooves 134, and to bring the upper surface of the oxide material 132 in the grooves 134 to substantially the same level as the upper surface of the shallow isolation trench 108 oxide.

Over the entire wafer surface, polysilicon is then recessed by an amount corresponding to the thickness of the polysilicon liner 130, resulting in a level wafer surface in both the memory cell array and support circuitry portions. In the memory cell array portion, the polysilicon recess merely diminishes the thickness of the polysilicon layer 129 to substantially the previous thickness of the polysilicon layer 129, before the polysilicon liner 130 had been deposited.

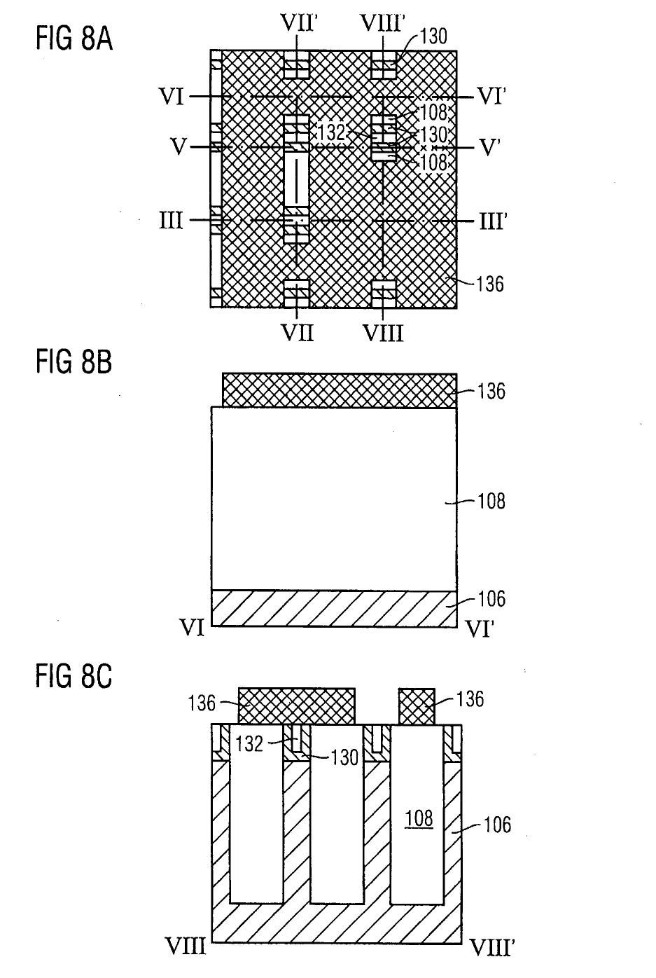

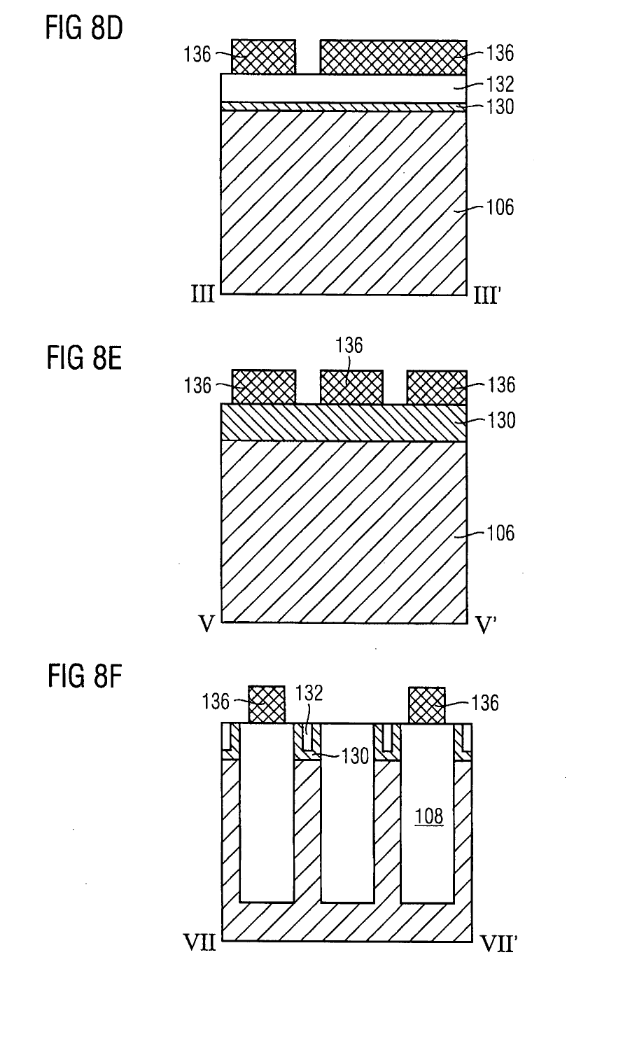

For formation of various transistor elements in the support circuitry section, a resist mask 136 is then deployed on the entire wafer surface. The resist mask 136 fully covers the memory cell array portion. In the support circuitry portion, however, it is lithographically patterned as exemplary shown in FIGS. 8A to 8F. Depending on the desired specifications of the support circuitry, the patterning may be chosen to form various circuit elements including transistors of different kinds. The patterning shown in FIGS. 8A to 8F merely has been chosen to demonstrate as an example the formation of three different types of transistors.

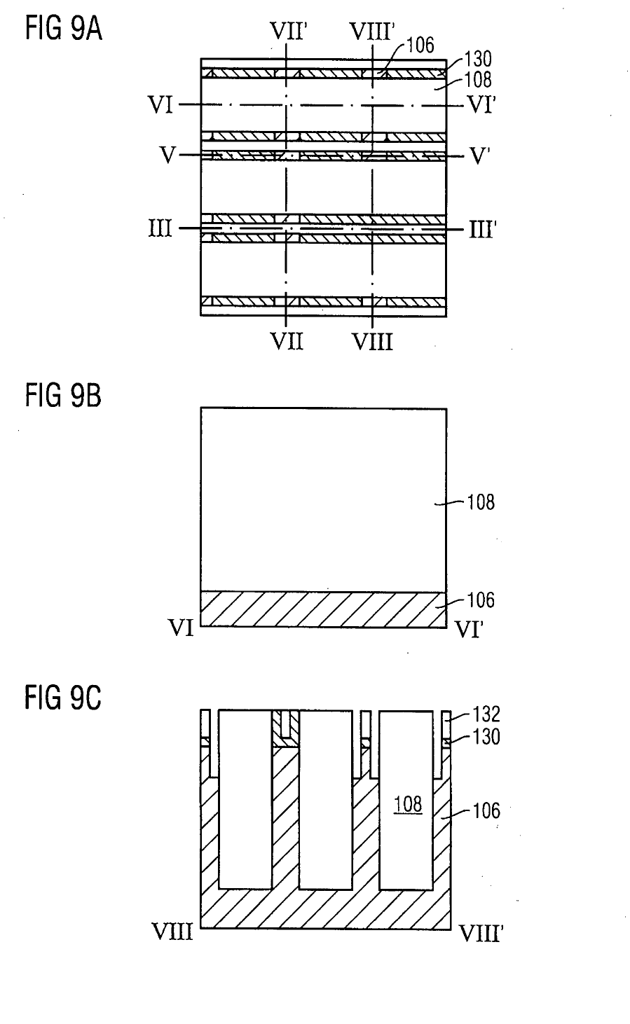

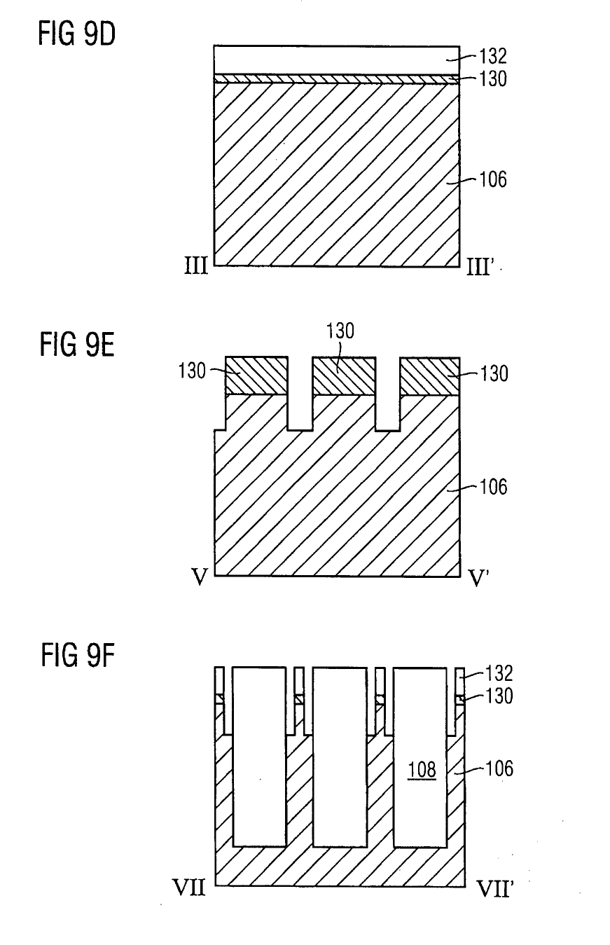

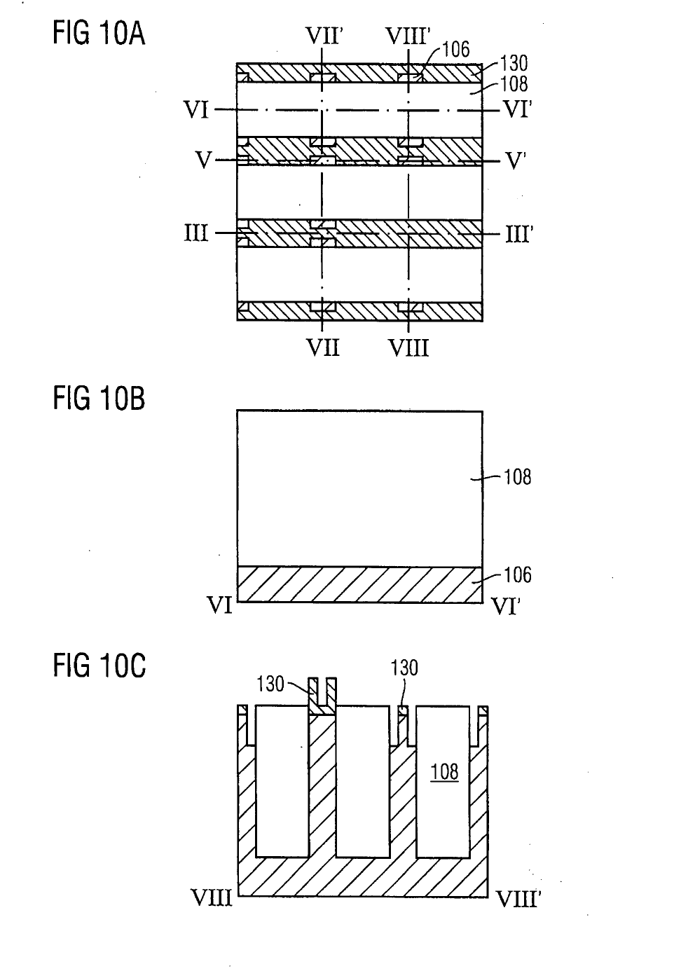

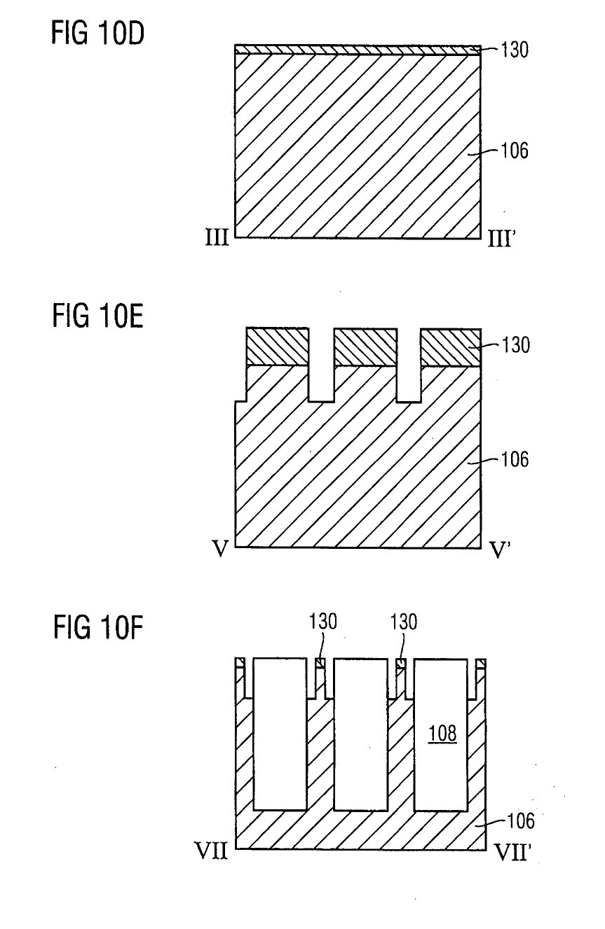

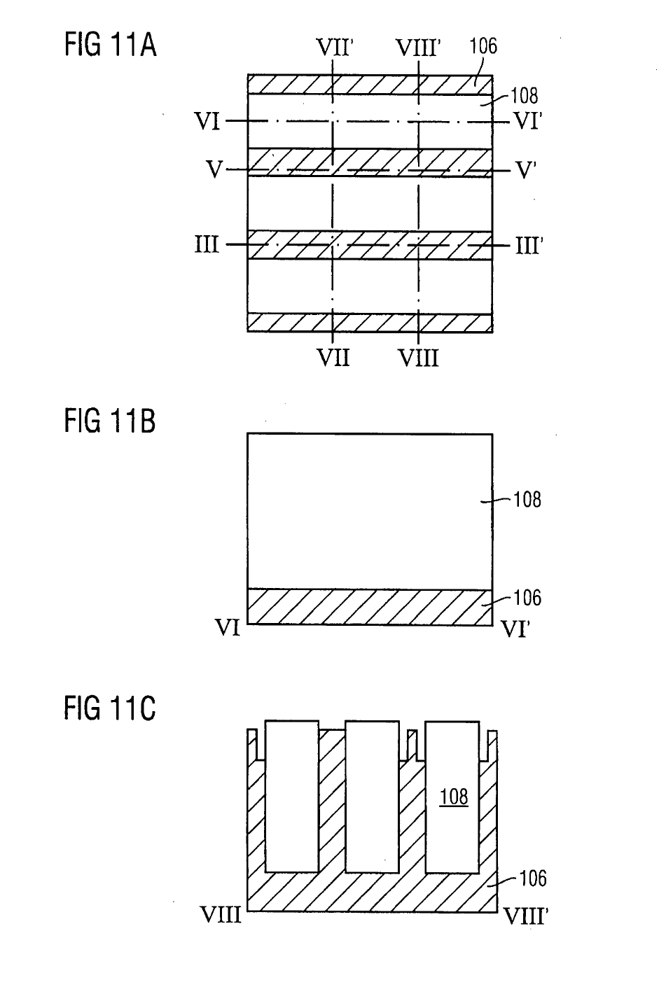

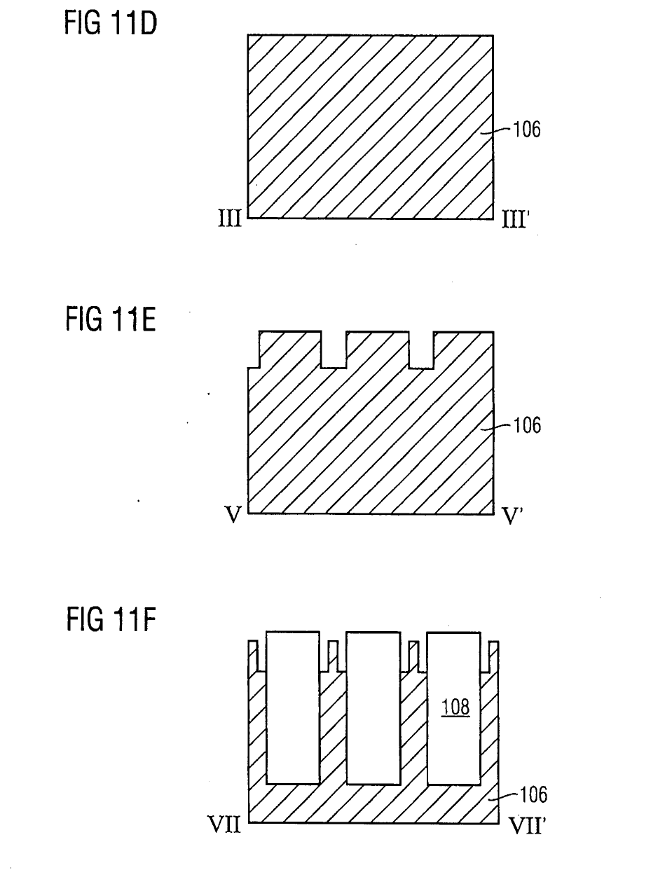

After deployment and patterning of the mask 136, an etching step that etches both monocrystalline 106 and polycrystalline 130 silicon is performed. FIGS. 9A to 9F show corresponding views of the structure compared to FIGS. 8A to 8F, respectively, after the etching of silicon and stripping of the mask. In a further etching step the result of which is shown in FIGS. 10A to 10F, oxide is recessed to such an extent that the top of the lowest-lying parts of the polysilicon liner 130 comes to lie at the same height as the top of the shallow isolation trench oxide filling 108. In a subsequent further etching step the polysilicon liner 130 is completely removed. The resulting structure, which is formed only of the substrate 106 and the shallow isolation trench oxide filling 108, is shown in FIGS. 11A to 11F. In the memory cell array portion, the polysilicon layer 129 remains intact while being thinned by an amount corresponding to the thickness of the polysilicon liner 130.

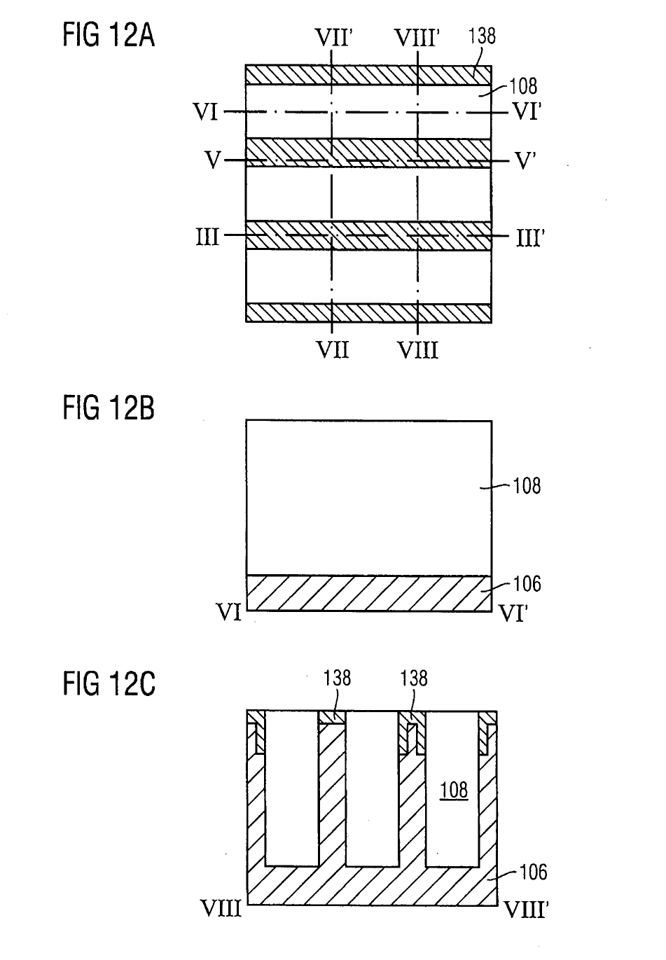

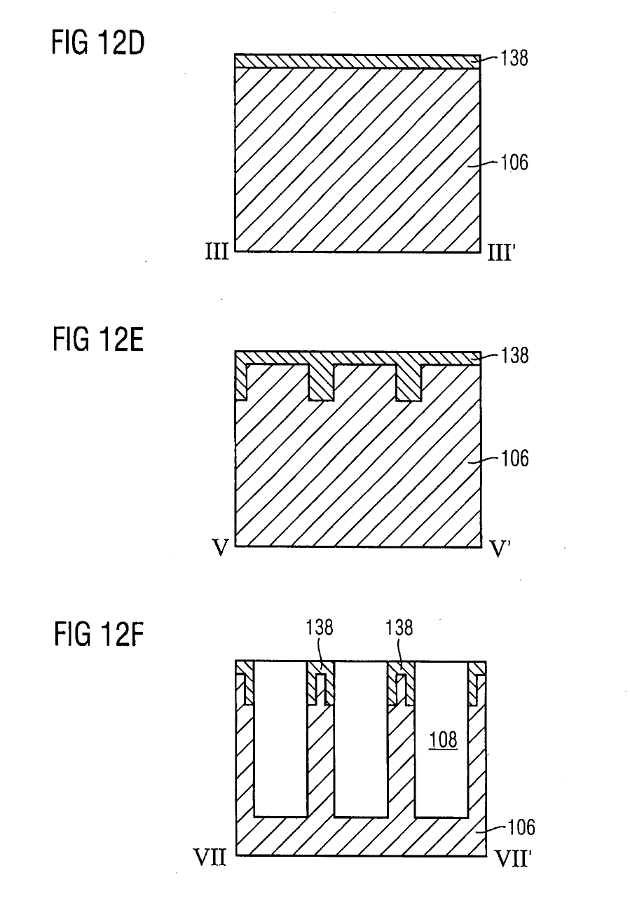

After a silicon thinning step in which the silicon substrate is recessed while the shallow isolation trench oxide filling 108 remains unaffected, a thin gate oxide layer (not shown) and polysilicon gate material 138 are deposited, followed by a recess of the polysilicon 138. In alternative embodiments, metal or a combination of metal and polysilicon is used as a gate material. The resulting structure in the support circuitry portion is shown in FIGS. 12A to 12F. In the memory cell array portion, no net change of the thickness of the polysilicon layer 129 results due to the balanced deposition and recess of the polysilicon gate material 138. Thus, the wafer surface at this stage is flat throughout in both the memory cell array and support circuitry portions.

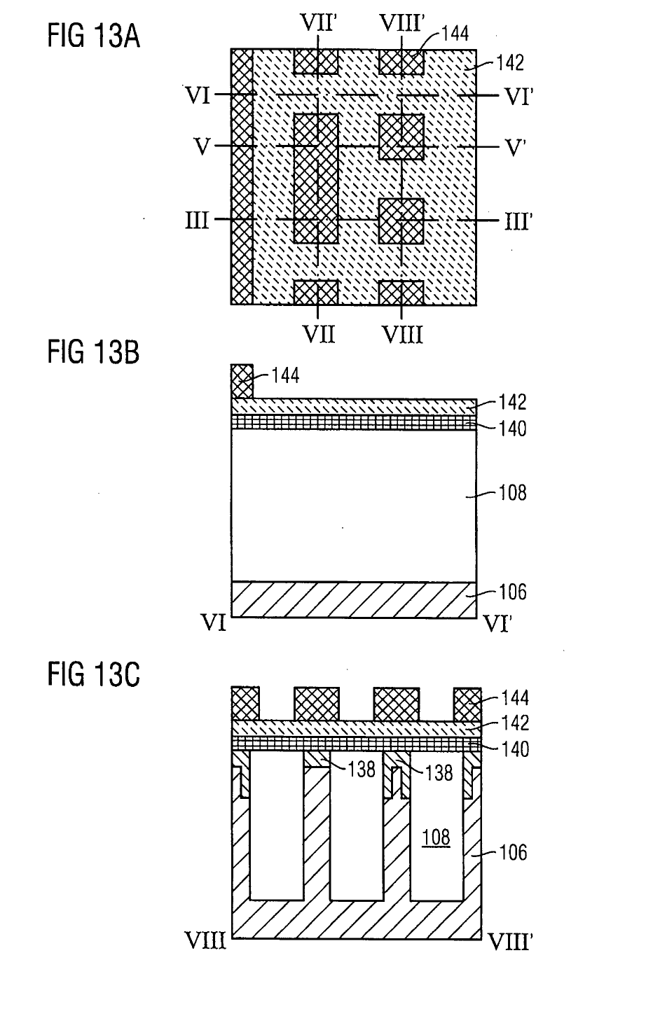

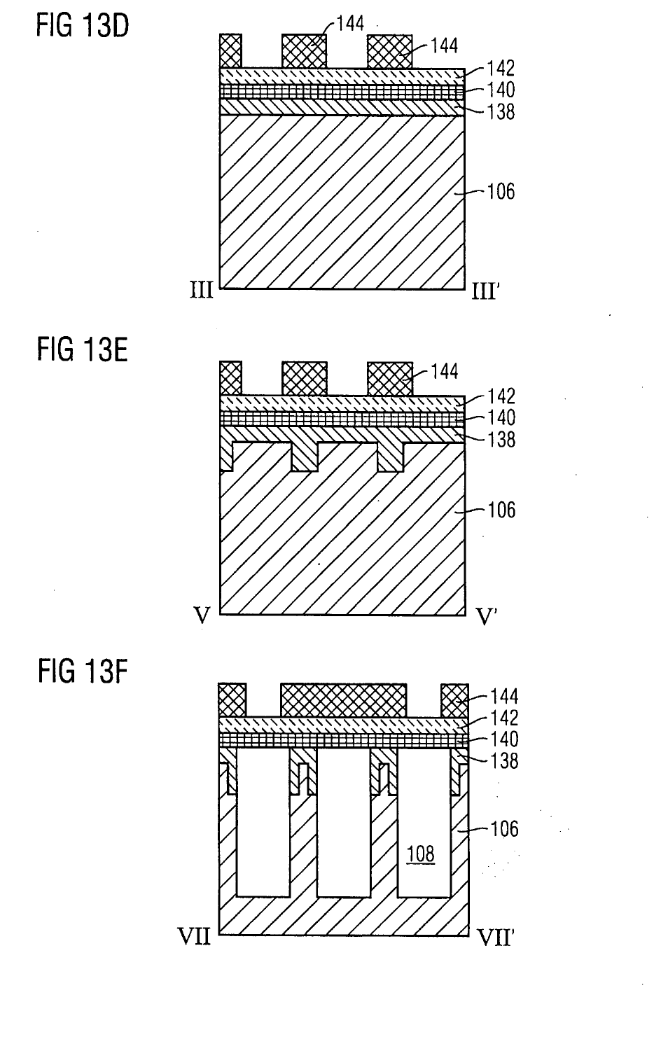

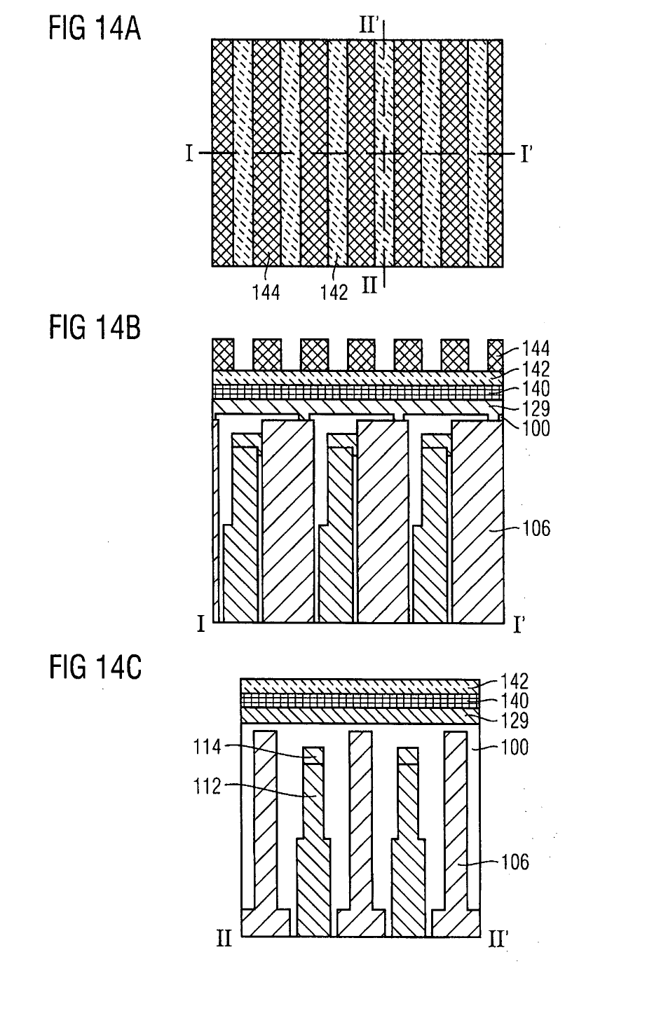

According to FIGS. 13A to 13F, following the formation of the transistor gates 138 a gate stack comprising a tungsten/tungsten nitride layer 140 and a silicon nitride cap layer 142 is deposited over the entire wafer surface. A resist mask 144 is deployed and patterned in the support circuitry portion of the wafer, shown in FIGS. 13A to 13F, as well as in the memory cell array portion of the wafer, shown in FIGS. 14A to 14F.

In a following step, the tungsten/tungsten nitride layer is etched on both the memory cell array and support circuitry portions in a single step. In alternative embodiments, separate resist masks may be provided in the memory cell array and support circuitry portions, respectively, and separate etching steps be carried out.

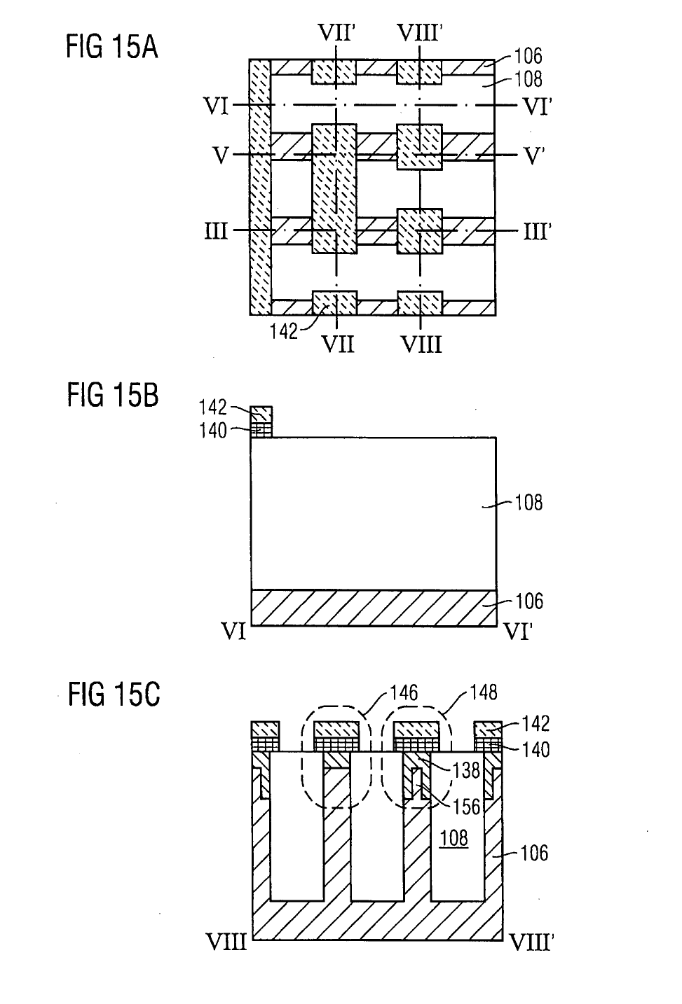

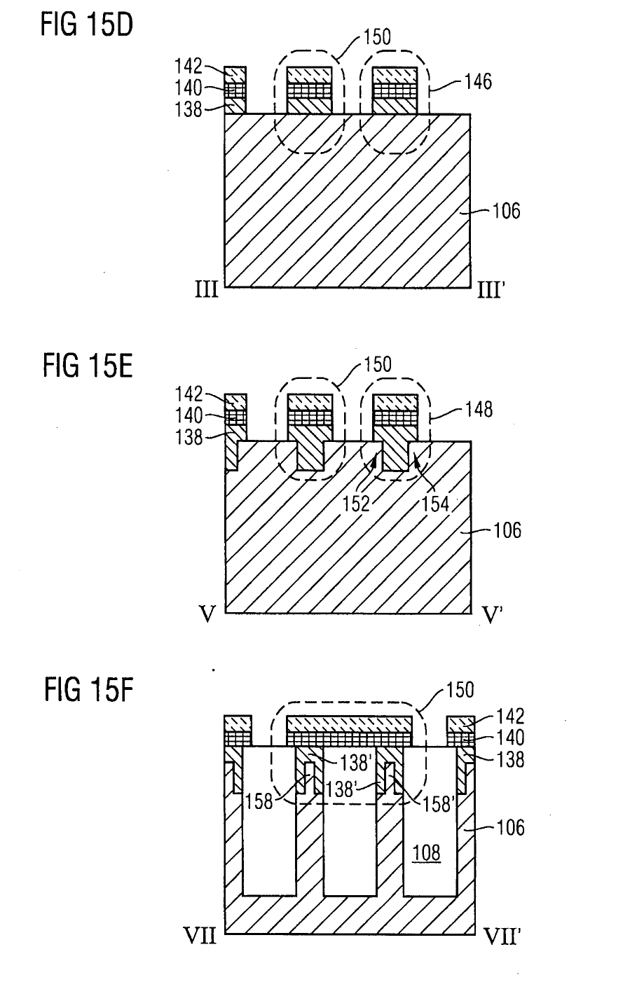

FIGS. 15A to 15F show the structure of the support circuitry portion after the tungsten/tungsten nitride layer 140 and the silicon nitride cap layer 142 has been etched and the resist mask 144 (no longer present) stripped. At this stage, three different transistor devices have been formed. These are, first, a conventional planar device 146, second, a FinFET device 148, and, third, a multi-FinFET device 150. The term “FinFET” refers to a field effect transistor (FET) comprising a first 152 and a second 154 source/drain portion. A channel 156 is disposed between the first and second source/drain portions 152, 154. A gate electrode 138 is insulated from the channel by a gate dielectric. In a FinFET, the channel 156 has the shape of a fin or ridge, as can be seen e.g. in FIG. 15C. Moreover, the gate electrode 138 encloses the channel 156 at two or three sides thereof. The term “multi-FinFET” refers to a FinFET 150 in which multiple fins 158, 158′ are formed that are controlled by a single, connected gate electrode structure 138′, 138″, e.g. a structure as shown in FIG. 15F comprising two polysilicon electrodes 138′, 138″ and their mutual connection by means of the tungsten/tungsten nitride layer 140.

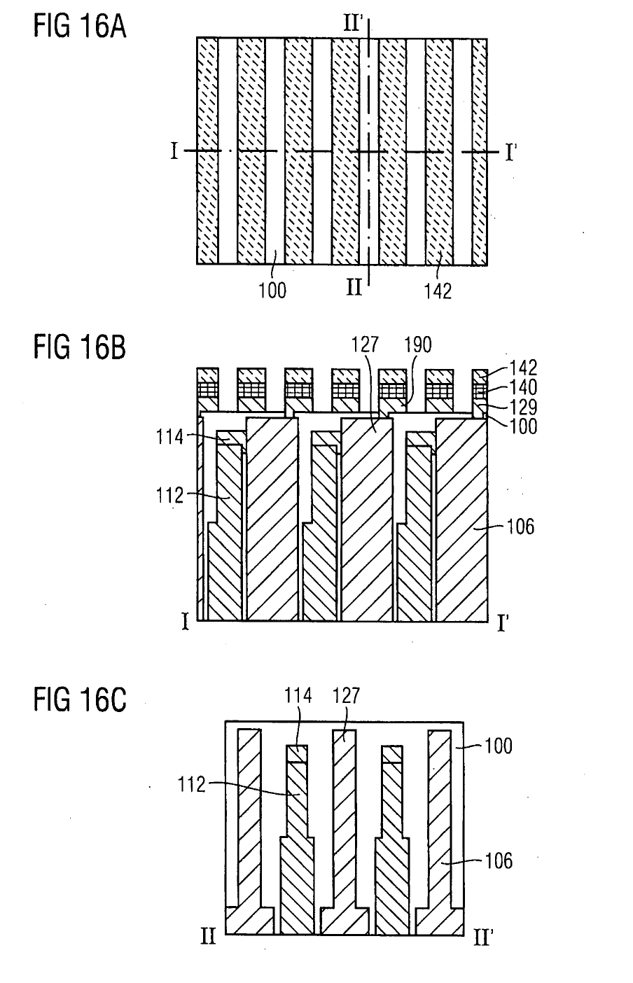

FIGS. 16A to 16C show the structure of the memory cell array portion after the tungsten/tungsten nitride layer 140 and the silicon nitride cap layer 142 has been etched and the resist mask 144 (no longer present) stripped. As can be seen in FIG. 16B, the polysilicon layer 129 has been divided into separate strips that in each memory cell contact the respective active area 127 of the substrate 106 and are configured to function as the bitlines 190 of the memory cell array. Their upper sides are disposed at the same height as the upper side of the gate electrodes 138, 138′, 138″ of the FinFET 148 and multi-FinFET 150, and are covered by the same tungsten/tungsten nitride layer 140.

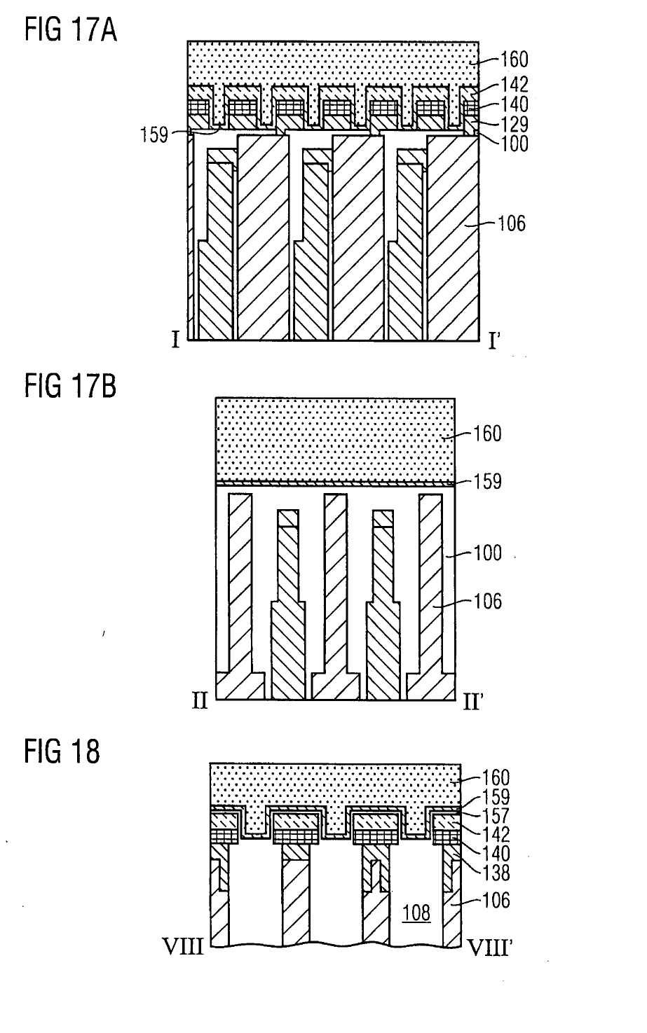

FIGS. 17 to 21 illustrate the subsequent formation of the wordlines of the memory cell array. First, a thin (e.g. 4 nm) spacer layer 157 of silicon oxide is deposited over the entire wafer surface and removed selectively over the memory cell array portion by a standard lithographic process. Then, a silicon nitride spacer of e.g. 12 nm is deposited over the entire wafer surface, followed by deposition of low-capacity, high-selectivity (LoCHiS) polysilicon 160 and chemical-mechanical planarization (CMP). While FIGS. 17A and 17B show the resulting structure in the memory cell array portion, FIG. 18 gives a cross-sectional view of the support circuitry portion at the same processing stage.

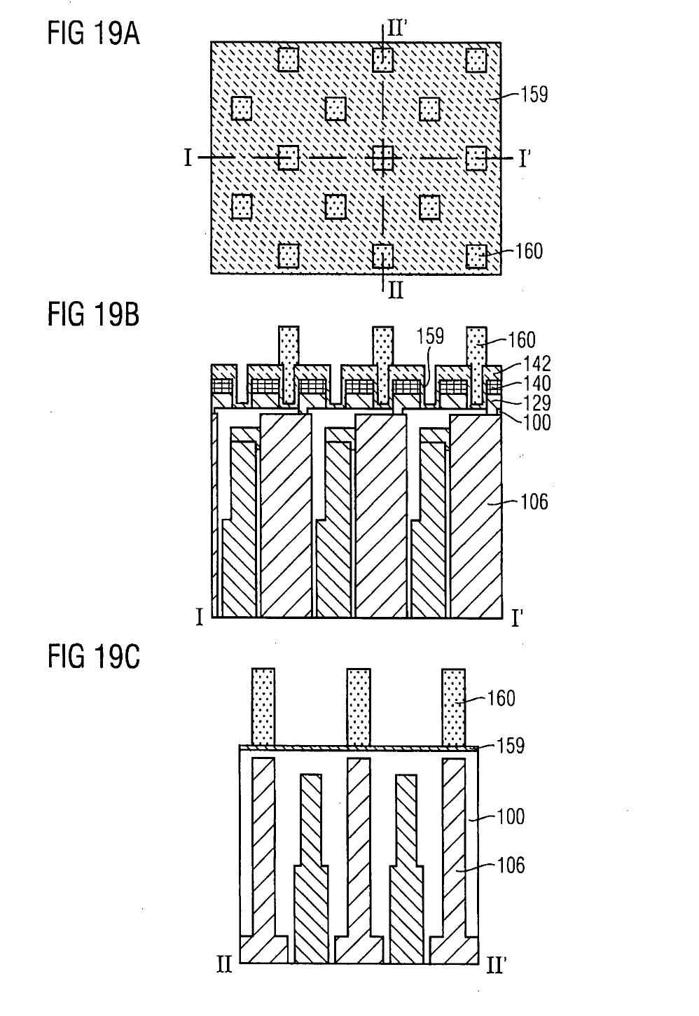

A hard mask is then deposited, the LoCHiS polysilicon 160 etched and the hard mask stripped, such that a structure such as shown in FIGS. 19A to 19C results in the memory array portion. Whereas the LoCHiS polysilicon is completely removed from the support circuitry portion, in the memory cell array portion columns 160 of LoCHiS polysilicon remain in positions where for each memory cell respective connections are to be formed to the wordlines of the memory cell array.

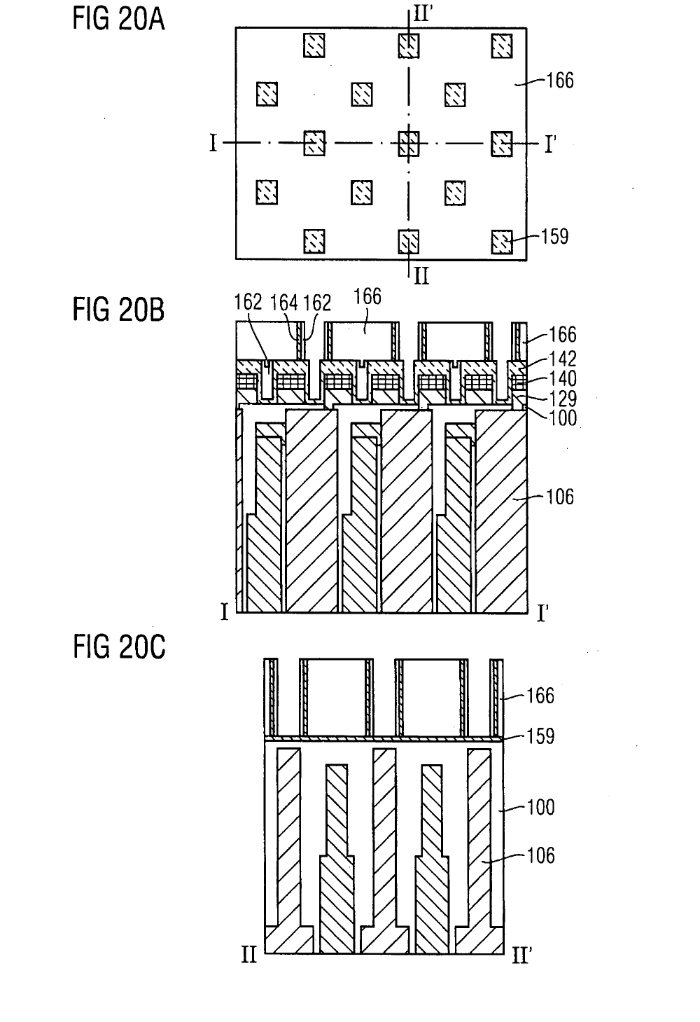

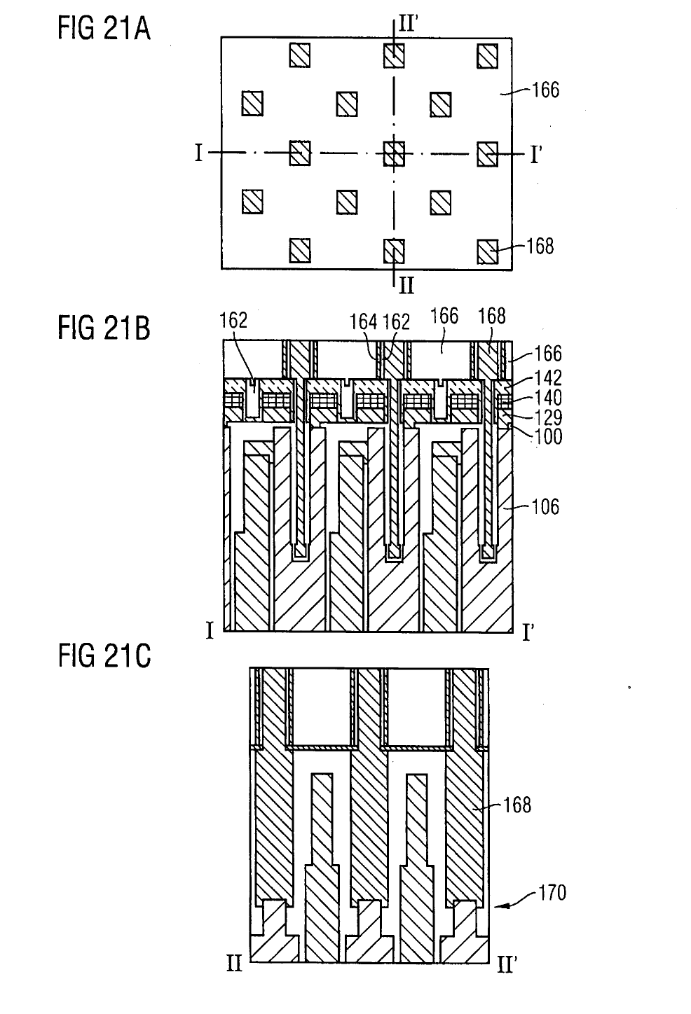

As can be seen in FIGS. 20A to 20C, an oxide spacer 162 and a further silicon nitride liner 164 are deposited in further processing steps, followed by filling with a spin-on dielectric 166 and chemical-mechanical planarization. Subsequent removal of the LoCHiS polysilicon 160 results in the structure shown in FIGS. 20A to 20C. Finally, by means of further processing steps such as a slit etch, silicon widening, spacer formation by low-pressure radical oxidation, deposition of a silicon liner, spacer opening, a further slit etch and silicon widening, isotropic oxide etch, low-pressure radical oxidation to form a gate oxide, and filling with doped polysilicon 168 the structure shown in FIGS. 21A to 21C is formed. Contacts of doped polysilicon 168 connect from the surface of the wafer where the wordlines are to be formed to a gate electrode with an extended U-groove 170.

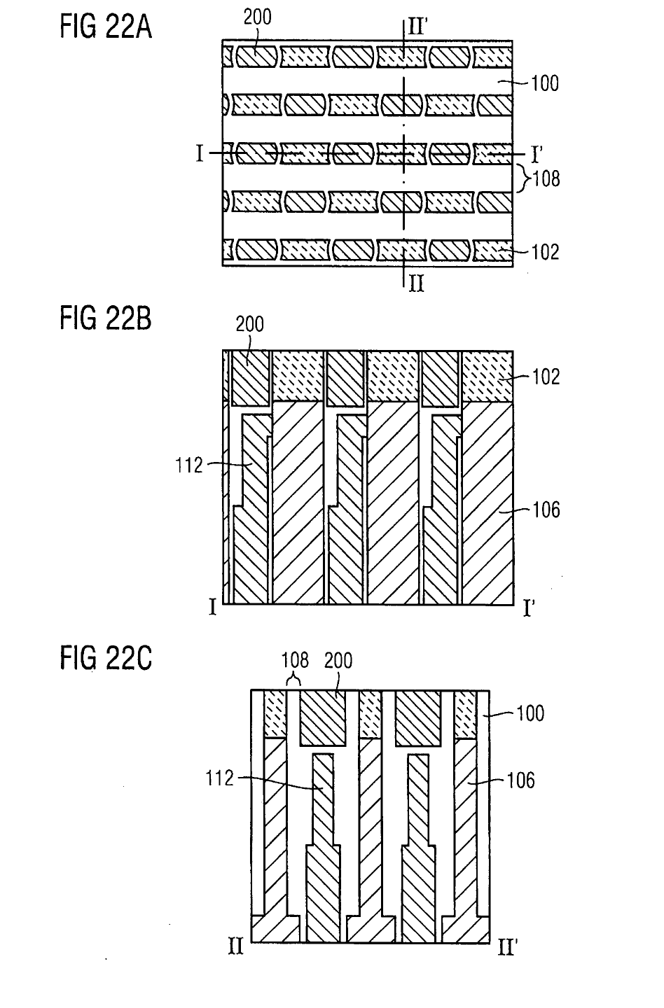

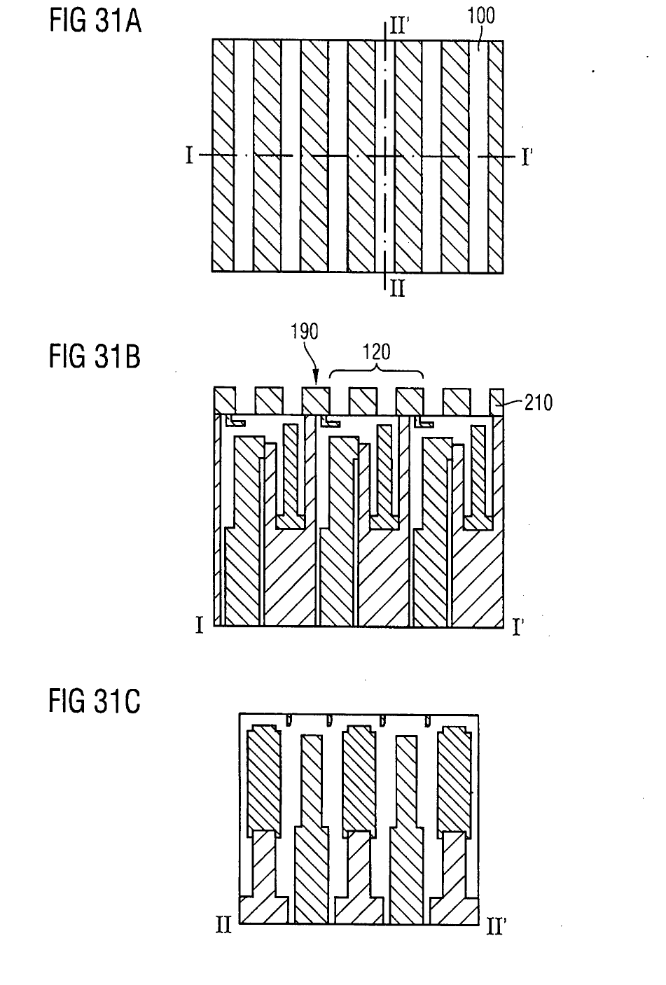

By making reference to FIGS. 22 to 31, another exemplary manufacturing process for manufacturing an integrated circuit based on a semiconductor substrate will now be explained according to a second embodiment. As in the first embodiment, the integrated circuit comprises a memory cell array portion and a support circuitry portion. During initial steps, the semiconductor substrate 106 is covered by a silicon nitride layer, followed by deep trench and storage condenser formation as in the first embodiment. Different from the first embodiment, an upper portion of each deep trench is filled with a polysilicon plug 200 isolated by an oxide liner from the surrounding substrate 106 and the inner condenser electrode 112 below. The wafer surface is flattened by CMP.

Subsequently, shallow isolation trenches are formed in both the memory cell array and support circuitry portions of the integrated circuit, resulting in a structure as shown in FIGS. 22A to 22C in the memory cell array portion. In the support circuitry portion, the same structure results as shown for the first embodiment in FIGS. 2A to 2C.

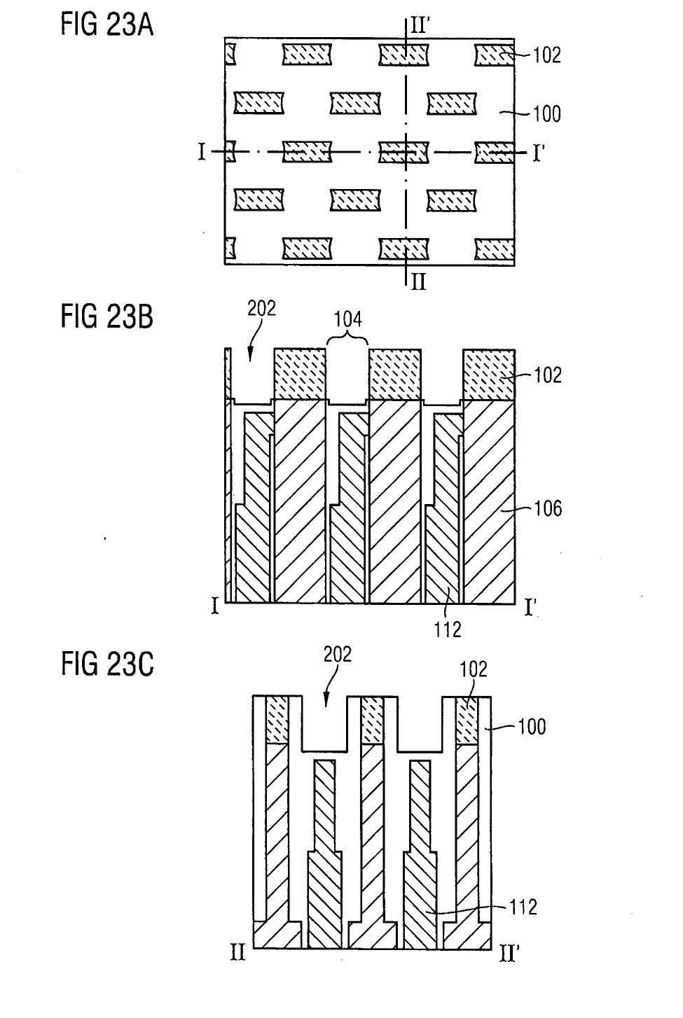

In further processing steps, the wafer is deglazed, e.g. to a depth of approximately 4 nm. The polysilicon plugs 200 are removed by reactive ion etching and cleaning, resulting in the structure shown in FIGS. 23A to 23C, where openings 202 can be seen to extend within the deep trenches 104 down to slightly below the top level of the silicon substrate 106.

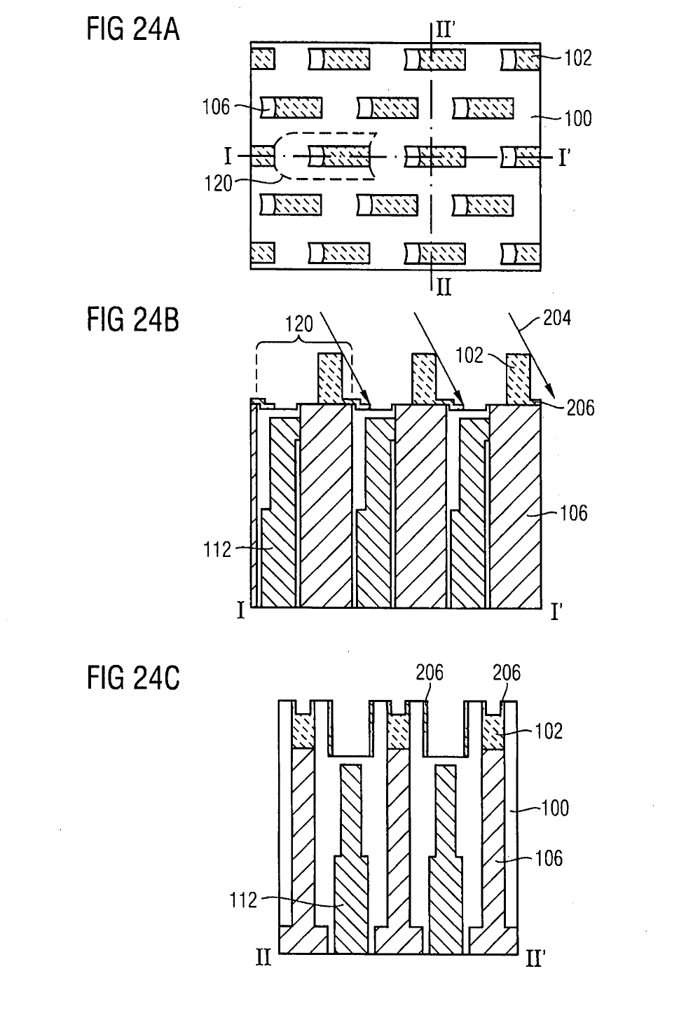

Subsequently, the silicon nitride islands 102 are pulled back, i.e. diminished in both height and width, by selective etching. Since the pullback is performed over the entire wafer surface, the silicon nitride strips 122 in the support circuitry portion (as shown e.g. in FIG. 2C for the first embodiment) are recessed as well. Then, the entire wafer surface is covered with a thin nitride liner, e.g. of 3 nm thickness. After performing a self-aligned tilt implant and subsequent wet development using dilute hydrofluoric acid (DHF), the structure shown in FIGS. 24A to 24C results. The direction of the tilt implant is indicated by arrows 204 in FIG. 24B. In each memory cell 120, a portion of the substrate 106 is exposed through a window in the vicinity of the connection to the inner condenser electrode 112.

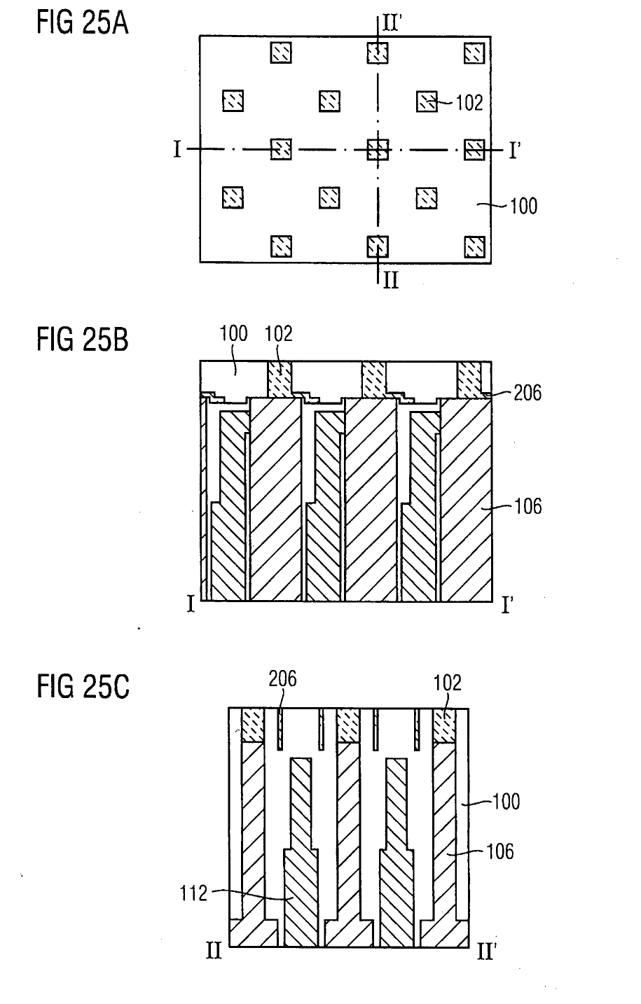

In a further step, the exposed portions of the silicon substrate 106 are recessed by anisotropic RIE. Subsequently, an oxide mask is deposited. The entire wafer surface is then flattened by CMP, restoring the support circuit portion to the state shown in FIGS. 2A to 2C. The state of the memory cell array portion at this point is shown in FIGS. 25A to 25C.

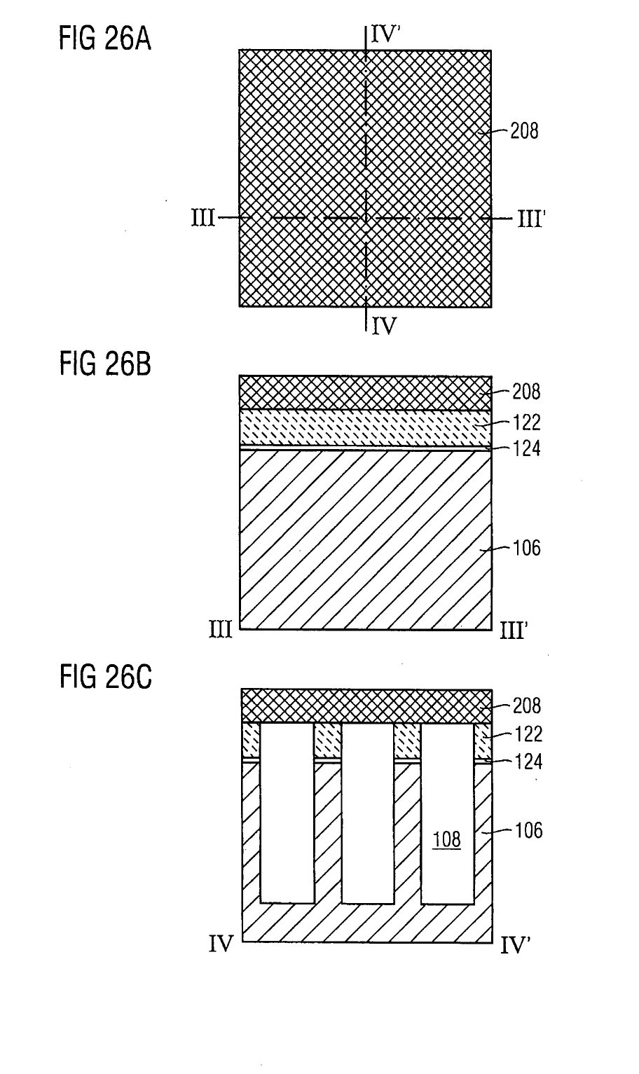

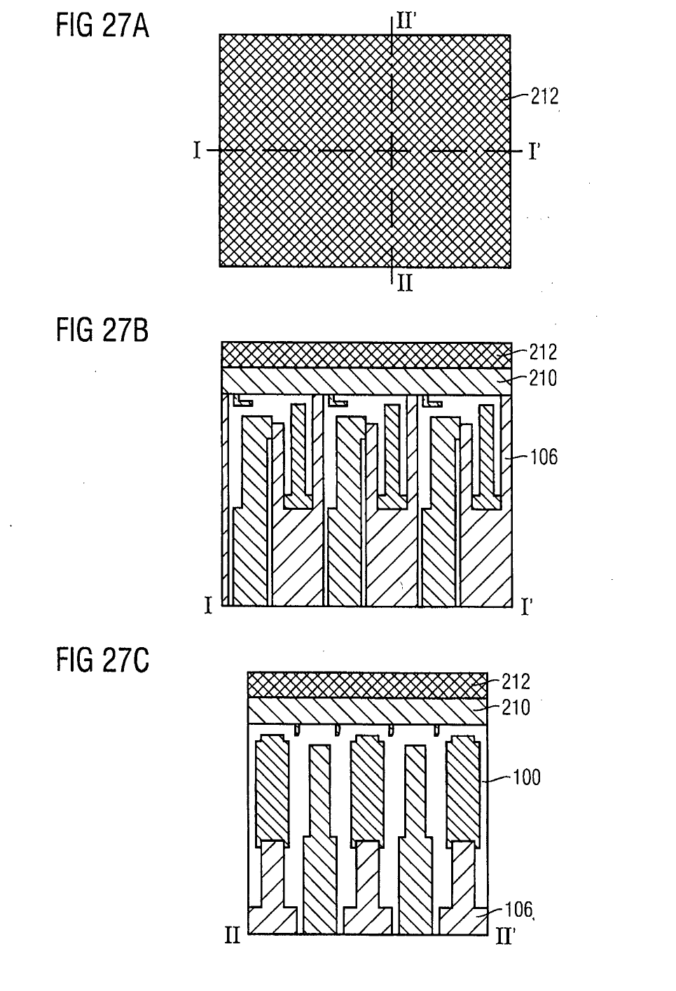

In order to perform further processing steps on the memory cell array portion without affecting the support circuitry portion, a hard mask 208 is then deposited on the support circuitry portion, as shown in FIGS. 26A to 26C. While the support circuitry portion is covered by the hard mask 208, silicon nitride is removed from the memory array portion, and further processing steps carried out that lead to the formation of a transistor in each memory cell 120. Final steps such as polysilicon fill and recess followed by silicon oxide fill, wet oxide recess, and stripping of silicon nitride are applied, leading to a flat surface of the wafer in the memory cell array portion. The entire wafer surface, including the hard mask 208 present on the support circuitry portion, is then covered by a layer of polysilicon 210. Hard mask 208 and polysilicon layer 210 are then removed from the support circuitry portion, while in turn the memory cell array portion is now covered by a mask layer 212. The resulting structure in the memory cell array portion is depicted in FIGS. 27A to 27C.

While the memory cell array portion remains protected under the hard mask layer 212, the support circuitry portion is processed as described above for the first embodiment, making reference to FIGS. 7 up to 12. The mask layer 212 is at this stage removed from the memory cell array portion.

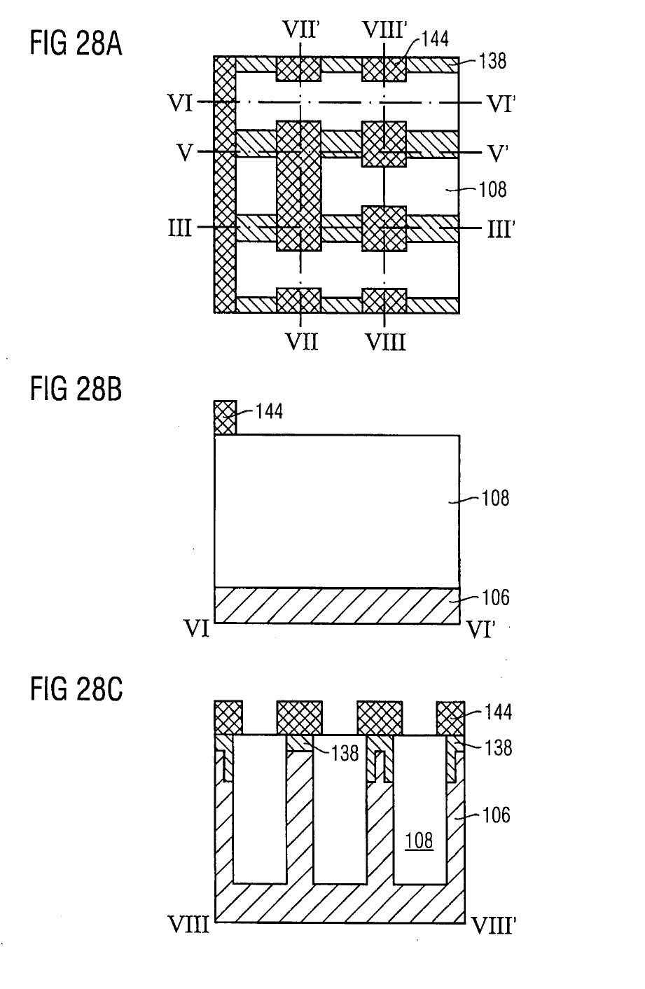

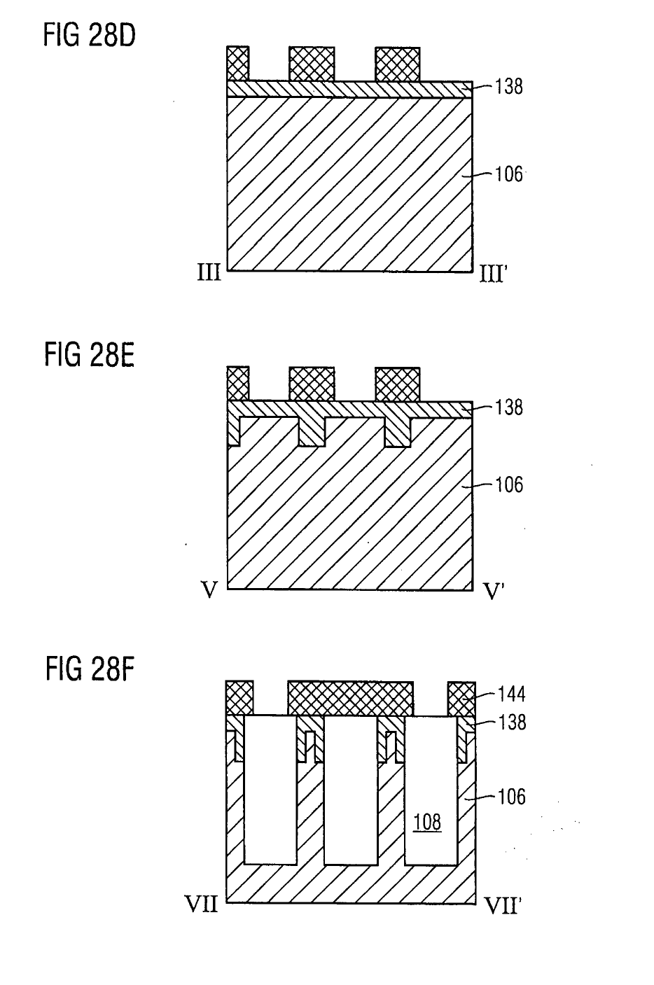

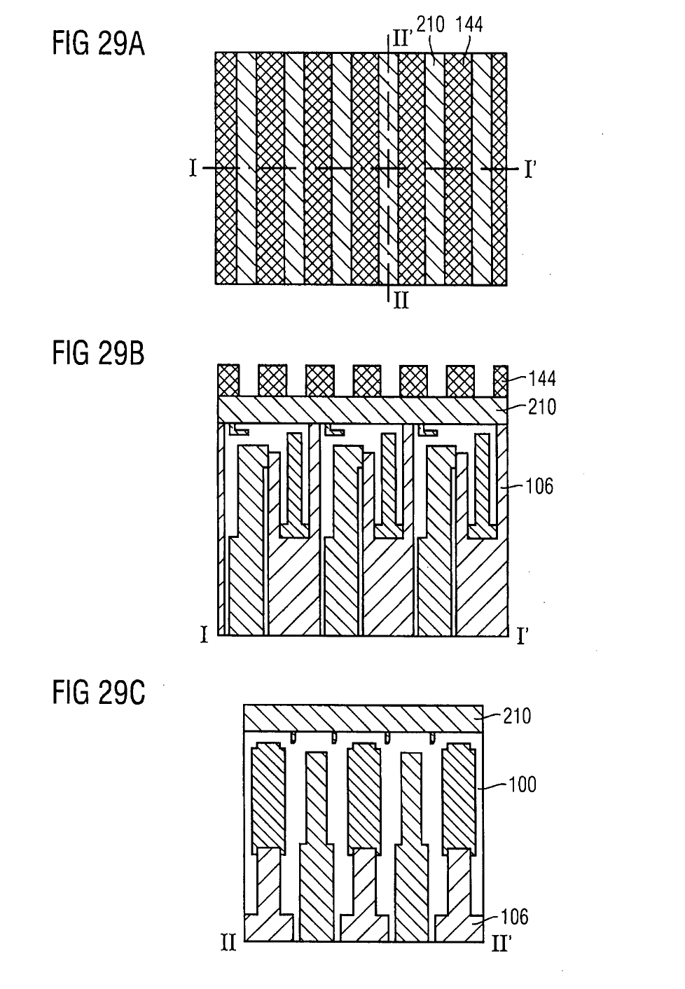

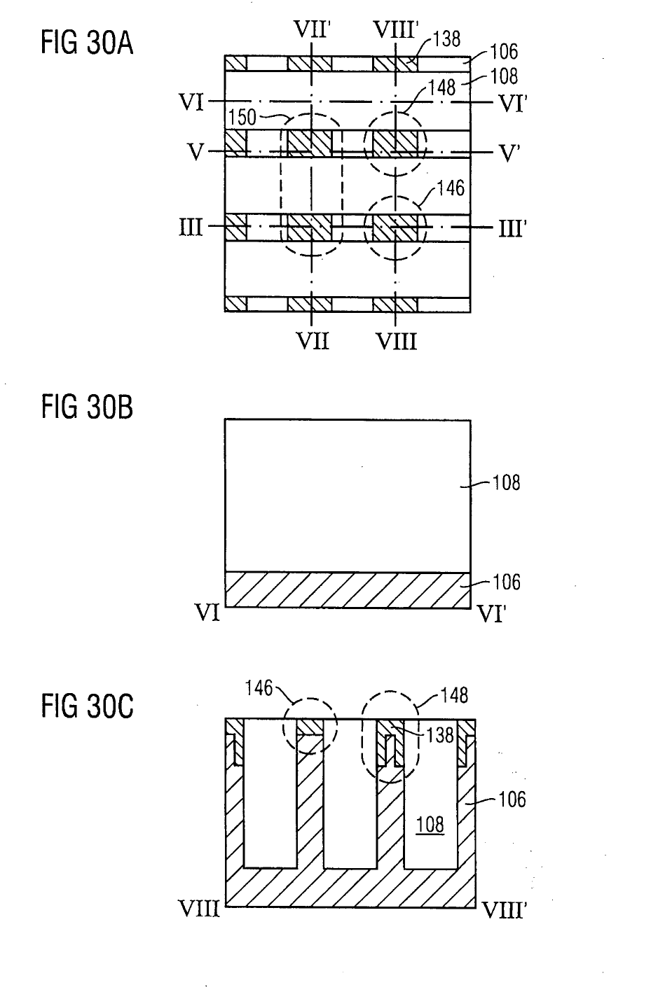

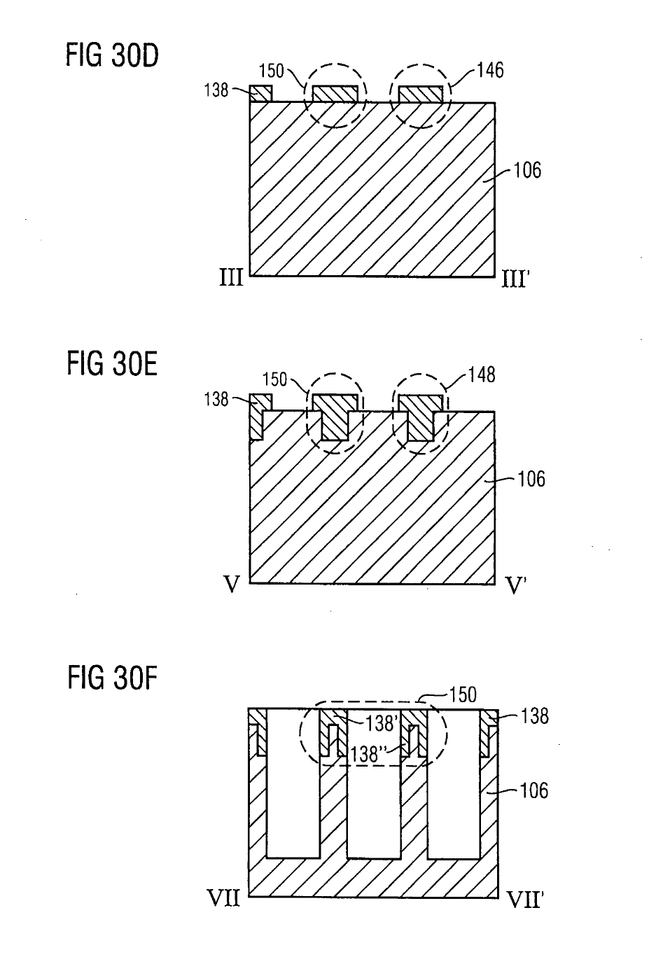

Different from the first embodiment, a lithographic mask 144 is deposited and patterned directly on the structure shown in FIGS. 12A to 12F in the support circuitry portion, and on the polysilicon layer 210 shown in FIG. 27A in the memory cell array portion, without previously depositing tungsten/tungsten nitride 140 and silicon nitride 142 layers as in the first embodiment. As shown in FIGS. 28A to 28F for the support circuit region and in FIGS. 29A to 29C for the memory cell array portion, the lithographic mask 144 is patterned essentially as shown and described for the first embodiment. Consequently, a planar transistor 146, a FinFET 148, and a multi-FinFET 150 are formed in the support circuit portion after etching of polysilicon 138 and stripping of the lithographic mask 144, as described above for the first embodiment and shown in FIGS. 30A to 30F. The partial gate electrodes 138′, 138″ of the multi-FinFET 150 are assumed to become electrically connected in a later processing step, which is omitted here.

Similarly, in the memory cell array portion as well, the lithographic mask 144 is patterned essentially as shown and described for the first embodiment with reference to FIGS. 16A to 16C. Consequently, bitlines 190 are formed from the polysilicon layer 212 that directly connect to the storage transistor of each memory cell, as described above for the first embodiment. As in the first embodiment, the upper side of the bitlines 190 formed is disposed at the same height as the upper sides of the gate electrodes 138, 138′, 138″ of both FinFETs 148, 150.

Although the present invention has been described with reference to preferred embodiments, it is not limited thereto, but can be modified in various manners which are obvious for a person skilled in the art. Thus, it is intended that the present invention is only limited by the scope of the claims attached herewith.

What is claimed is:

1. An integrated circuit, comprising:
a memory cell array portion comprising at least one bitline and at least one wordline, the wordline disposed above the bitline; and
a support circuitry portion, the support circuitry portion comprising a FinFET, the FinFET comprising a gate electrode;
wherein an upper side of a portion of the gate electrode is disposed at the same height as an upper side of a portion of the bitline.

2. The integrated circuit of claim 1, configured as one selected from the group consisting of Random Access Memory, Erasable Programmable Read-Only Memory, Flash Memory, and Read-Only Memory.

3. The integrated circuit of claim 1, wherein a portion of the gate electrode and a portion of the bitline are formed of the same layer.

4. The integrated circuit of claim 1, wherein the memory cell array portion comprises first isolation trenches and the support circuitry portion comprises second isolation trenches, the first and second isolation trenches extending to the same depth.

5. The integrated circuit of claim 1, wherein the FinFET comprises a gate electrode, the gate electrode and the bitline comprising the same material.

6. The integrated circuit of claim 1, wherein the FinFET comprises at least two gate electrodes.

7. The integrated circuit of claim 1, the support circuitry portion further comprising a planar transistor.

8. A data processing system comprising an integrated circuit, the integrated circuit comprising:
a memory cell array formed in a first portion of a semiconductor substrate;
at least one bitline and at least one wordline formed in the first portion, the wordline disposed above the bitline; and
a support circuitry formed in a second portion of the semiconductor substrate, the support circuitry comprising a FinFET;
wherein the FinFET comprises a gate electrode, an upper side of a portion of the gate electrode being disposed at the same height as an upper side of a portion of the bitline.

9. The data processing system of claim 8, wherein a portion of the gate electrode and a portion of the at least one bitline are formed of the same layer.

10. An electronic device comprising an integrated circuit, the integrated circuit comprising:
a memory cell array portion comprising at least one bitline and at least one wordline, the wordline disposed above the bitline; and
a support circuitry portion, the support circuitry portion comprising a FinFET, the FinFET comprising a gate electrode;
wherein an upper side of a portion of the gate electrode is disposed at the same height as an upper side of a portion of the bitline.

11. The electronic device according to claim 10, wherein a portion of the gate electrode and a portion of the bitline are formed of the same layer.

12. The electronic device according to claim 10, further comprising components to implement an electronic system that is selected from the group consisting of a computer, a server, a router, a game console, a graphics card, a personal digital assistant, a digital camera, a cell phone, an audio system, a video system and processing device.

13. A method of manufacturing an integrated circuit, comprising:
forming a memory cell array; and
forming a support circuitry;
wherein
the forming of the memory cell array comprises forming a bitline and forming a wordline disposed above the bitline;
the forming of the support circuitry comprises forming a FinFET; and
the forming of the FinFET comprises forming a gate electrode, an upper side of a portion of the gate electrode being formed at the same height as an upper side of a portion of the bitline.

14. The method of claim 13, wherein the forming of the gate electrode and the forming of the bitline comprise a common etching process.

15. The method of claim 13, wherein the forming of the gate electrode and the forming of the bitline comprise a common deposition process.

16. The method of claim 13, wherein the forming of the memory cell array comprises forming first isolation trenches, and the forming of the support circuitry comprises forming second isolation trenches, wherein the forming of the first isolation trenches and the forming of the second isolation trenches comprise common etching processes.

17. The method of claim 13, wherein the forming of the support circuitry further comprises forming a planar transistor.

18. The method of claim 13, wherein the forming of the FinFET comprises forming at least two gate electrodes.

19. A method of manufacturing an integrated circuit, comprising:
defining a first and a second portion of a semiconductor substrate;
forming a memory cell array in the first portion, the memory cell array comprising at least one bitline and at least one wordline, the wordline disposed above the bitline; and
forming a support circuitry in the second portion, the support circuitry comprising a FinFET, the FinFET comprising a gate electrode;
wherein an upper side of a portion of the gate electrode and an upper side of a portion of the bitline are formed at the same height.

20. The method of claim 19, wherein the forming of the memory cell array comprises:
covering the second portion of the semiconductor substrate by a layer of a first material;
performing an etching process that does not remove the layer of the first material; and
removing the layer of the first material.

21. The method of claim 20, wherein the performing of the etching process reduces a thickness of the layer of the first material.

22. The method of claim 19, wherein the forming of the support circuitry comprises:
covering the first portion of the semiconductor substrate by a layer of a second material;
performing an etching process that does not remove the layer of the second material; and
removing the layer of the second material.

23. The method of claim 22, wherein the performing of the etching process reduces a thickness of the layer of the second material.
